(19) United States
(12) Patent Application Publication
(10) Pub. No.: US 2009/0102365 A1
(43) Pub. Date: Apr. 23, 2009

(54) Method for manufacturing luminous particle, method for manufacturing material liquid for formation of luminous element, method for manufacturing organic el display device, luminous particle, material liquid, organic el display device, and method for manufacturing organic compound particle formation of charge transfer element, method for manufacturing material liquid for formation of charge transfer element, and organic compound particle

(75) Inventors: Kiyohiko Takemoto, Matsumoto-shi (JP); Miharu Kanaya, Azumino-shi (JP)

Correspondence Address: EDWARDS ANGELL PALMER & DODGE LLP, P.O. BOX 55874, BOSTON, MA, 02205, US

(73) Assignee: Seiko Epson Corporation, Tokyo (JP)

(21) Appl. No.: 12/231,345

(22) Filed: Sep. 2, 2008

(30) Foreign Application Priority Data
Aug. 30, 2007 (JP) 2007-223565
Jul. 16, 2008 (JP) 2008-184650
Aug. 26, 2008 (JP) 2008-216287
Aug. 28, 2008 (JP) 2008-220376

(51) Int. Cl. H01J 1/63; C09K 11/06; B05D 5/00

(52) U.S. Cl. 313/504; 252/301.16; 427/66

(57) ABSTRACT

A method for manufacturing luminous element particles, comprising: forming a luminous element layer, containing a release layer and luminous organic compound layer, on at least one side of a base material; and micro-fragmenting the luminous element layer after separating the same from the one side of the base material.

### CROSS-REFERENCES TO RELATED APPLICATIONS

The present application incorporates the contents of Japanese Patent Application No. 2008-220376 filed on Aug. 28, 2008, Japanese Patent Application No. 2008-216287 filed on Aug. 26, 2008, Japanese Patent Application No. 2008-184650 filed on Jul. 16, 2008, and Japanese Patent Application No. 2007-223565 filed on Aug. 30, 2007.

### BACKGROUND

1. Technical Field

The present invention relates to a technology for manufacturing an organic electroluminescence (EL) display device, such as a method for manufacturing luminous element particles.

2. Related Art

Luminous devices using organic EL materials have come to be increasingly used in lighting applications due to their low power consumption and high luminous efficiency.

In addition, organic EL display devices, manufactured by forming organic luminous layers using organic EL materials into specific shapes, are superior in terms of response speed, service life and power consumption, and are expected to become the mainstream of thin displays in the future in place of plasma luminous display devices and liquid crystal display devices.

However, the manufacturing of organic EL display devices in particular has various problems. For example, in the case of forming an organic luminous layer of a specific shape by a deposition method, a mask of the corresponding shape is required, thus making the process complex and the device complicated. In addition, since only about several percent to several tens of percent of an evaporated organic material can be used, expensive organic materials end up being wasted thereby resulting in high manufacturing costs as well.

Therefore, studies have been conducted to reduce material waste by forming luminous layers of specific shapes by an inkjet printing method (see, for example, JP-A-10-12377 and JP-A-10-153967).

However, in order to obtain a liquid for discharging a luminous organic compound with an inkjet head, it is necessary to use a luminous organic compound of a comparatively high molecular weight that dissolves in an organic solvent. Consequently, the materials that can be used are limited, and it was difficult to obtain a display device having a long service life.

In addition, material waste due to the use of the deposition method and limitations on materials able to be used when using an inkjet method are present not only with respect to the organic luminous layer, but also with respect to hole transport layers, electron transport layers, hole injection layers and electron injection layers used in organic EL display devices, thereby resulting in the similar problem of it being difficult to manufacture a layer allowing injection and transport of large amounts of charge at low voltages.

### SUMMARY

Therefore, an advantage of a specific aspect of the invention is to provide a technology for manufacturing a high-performance organic EL display device capable of carrying out high-precision patterning both easily and in a short period of time.

1. A method for manufacturing luminous element particles according to the invention, includes: forming a luminous element layer, containing a release layer and luminous organic compound layer, on at least one side of a base material; and micro-fragmenting the luminous element layer after separating the same from the one side of the base material. According to this method, luminous element particles having satisfactory characteristics can be formed easily.

For example, the micro-fragmentation involves micro-fragmenting the luminous layer while stripping from the base material. This may be carried out chemically by, for example, immersing a sheet-like base material in an organic solvent. In addition, this may also be carried out mechanically (physically) by a spatula-shaped member. In addition, during the micro-fragmentation, for example, ultrasonic waves may be applied to the luminous element layer. According to this method, separation and micro-fragmentation are promoted by ultrasonic waves.

The release layer is formed with resin, for example, and is preferably formed with wax.

2. A method for manufacturing a material liquid for forming a luminous element according to an aspect of the invention includes: forming a luminous element layer, containing a release layer and a luminous organic compound layer, on at least one side of a base material; forming luminous element particles by micro-fragmenting the luminous element layer after separating the same from the one side of the base material; and preparing a material liquid for forming a luminous element by adding a second organic solvent to the luminous element particles. According to this method, a material liquid for forming a luminous element having satisfactory characteristics can be formed easily.

The release layer is formed with resin, for example, and is preferably formed with wax.

3. A method for manufacturing an organic EL display device according to an aspect of the invention includes: forming a luminous element layer, containing a release layer and a luminous organic compound layer, on at least one side of a base material, forming luminous element particles by micro-fragmenting the luminous element layer after separating the same from the one side of the base material, preparing a material liquid for forming a luminous element by adding a second organic solvent to the luminous element particles, and forming a luminous layer by dropping the material liquid onto a substrate and solidifying thereon. According to this method, a luminous layer having satisfactory characteristics can be formed easily. In addition, various materials can be used for the luminous organic compound, and for example, a low molecular weight material resistant to dissolution (dispersion) in organic solvent can be used.

For example, the micro-fragmentation involves micro-fragmenting the luminous layer while stripping from the base material. This may be carried out chemically by, for example, immersing a sheet-like base material in an organic solvent. In addition, this may also be carried out mechanically (physically) by a spatula-shaped member. In addition, during the micro-fragmentation, for example, ultrasonic waves may be applied to the luminous element layer. According to this method, separation and micro-fragmentation are promoted by ultrasonic waves.

A method for manufacturing an organic EL display device according to an aspect of the invention includes: forming a luminous element layer, containing a release layer and a luminous organic compound layer, on at least one side of a sheet-like base material; forming luminous element particles by immersing the sheet-like base material in a first organic solvent and occasionally separating a portion of the luminous organic compound layer from the release layer and micro-fragmenting the same; preparing a material liquid using the first organic solvent containing the luminous element particles; and forming a luminous layer by dropping the material liquid onto a substrate and solidifying thereon. According to this method, a luminous layer having satisfactory characteristics can be formed easily due to particle leafing effects. In addition, various materials can be used for the luminous organic compound, and for example, a low molecular weight material resistant to dissolution (dispersion) in organic solvent can be used. In addition, a material liquid allowing the formation of a luminous layer in a short process can be prepared by using a first organic solvent.

For example, formation of the luminous layer involves the formation of a luminous layer by discharging the material liquid onto a desired region on the substrate by a liquid droplet jetting method followed by solidifying the material liquid on the substrate. The use of a liquid droplet jetting method allows the formation of a luminous layer having satisfactory characteristics at low cost.

The release layer is formed with resin, for example, and is preferably formed with wax.

A method for manufacturing an organic EL display device according to an aspect of the invention includes: forming a luminous layer using luminous element particles or a material liquid formed according to the method for manufacturing luminous element particles or the method for manufacturing a material liquid for forming a luminous element. According to this method, a luminous layer having satisfactory characteristics can be formed easily due to particle leafing effects.

4. Luminous element particles according to an aspect of the invention are luminous element particles formed by micro-fragmenting a luminous element layer, containing a release layer and a luminous organic compound layer, after separating the same from a base material on which the luminous element layer is formed, wherein each of the particles is in the form of leaves (or scales). According to this configuration, the resulting material is satisfactory for forming a luminous element.

The release layer is formed with resin, for example, and is preferably formed with wax.

The material liquid according to an aspect of the invention contains the luminous element particles. According to this configuration, the resulting material is satisfactory for forming a luminous element.

An organic EL display device according to an aspect of the invention has a luminous layer formed by solidifying the material liquid. According to this configuration, a luminous layer having satisfactory characteristics is easily formed due to leafing effects of the particles.

For example, the molecular weight of the luminous organic compound in the luminous layer is 1000 or less. The use of a low molecular weight material resistant to dissolution (or dispersal) in organic solvent in this manner improves the characteristics of the device.

5. A method for manufacturing organic compound particles for forming a charge transfer element according to an aspect of the invention includes: forming a laminate layer, containing a release layer and an organic compound layer having charge transferability, on at least one side of a base material; and micro-fragmenting the laminate layer after separating the same from the one side of the base material. According to this method, organic compound particles for forming a charge transfer element having satisfactory characteristics can be formed easily.

For example, the micro-fragmentation involves micro-fragmenting the laminate layer while stripping from the base material. This may be carried out chemically by, for example, immersing a sheet-like base material in an organic solvent. In addition, this may also be carried out mechanically (physically) by a spatula-shaped member. In addition, during the micro-fragmentation, for example, ultrasonic waves may be applied to the laminate layer. According to this method, separation and micro-fragmentation are promoted by ultrasonic waves.

The release layer is formed with resin, for example, and is preferably formed with wax.

6. A method for manufacturing a material liquid for forming a charge transfer element according to an aspect of the invention includes: forming a laminate layer, containing a release layer and an organic compound layer having charge transferability, on at least one side of a base material; forming organic compound particles by micro-fragmenting the laminate layer after separating the same from the one side of the base material; and preparing a material liquid for forming a charge transfer element by adding a second organic solvent to the organic compound particles. According to this method, a material liquid for forming a charge transfer element having satisfactory characteristics can be formed easily.

The release layer is formed with resin, for example, and is preferably formed with wax.

In addition, the micro-fragmentation involves micro-fragmenting the laminate layer while stripping from the base material. This may be carried out chemically by, for example, immersing a sheet-like base material in an organic solvent. In addition, this may also be carried out mechanically (physically) by a spatula-shaped member. In addition, during the micro-fragmentation, for example, ultrasonic waves may be applied to the laminate layer. According to this method, separation and micro-fragmentation are promoted by ultrasonic waves.

7. A method for manufacturing an organic EL display device according to an aspect of the invention includes: forming a laminate layer, containing a release layer and an organic compound layer having charge transferability, on at least one side of a base material; forming organic compound particles by micro-fragmenting the laminate layer after separating the same from the one side of the base material; preparing a material liquid by adding a second organic solvent to the organic compound particles; and forming a charge transfer layer by dropping the material liquid onto a substrate and solidifying thereon. According to this method, a charge transfer layer having satisfactory characteristics can be formed easily. In addition, various materials can be used for the organic compound having charge transferability, and for example, a low molecular weight material resistant to dissolution (dispersion) in organic solvent can be used.

A method for manufacturing an organic EL display device according to an aspect of the invention includes: forming a laminate layer, containing a release layer and an organic compound layer having charge transferability, on at least one side of a sheet-like base material; forming organic compound particles by immersing the sheet-like base material in a first organic solvent and occasionally separating a portion of the organic compound layer after from the release layer and micro-fragmenting the same; preparing a material liquid using the first organic solvent containing the organic compound particles; and forming a charge transfer layer by dropping the material liquid onto a substrate and solidifying thereon. According to this method, a charge transfer layer having satisfactory characteristics can be formed easily due to particle leafing effects. In addition, various materials can be used for the organic compound having charge transferability, and for example, a low molecular weight material resistant to dissolution (dispersion) in organic solvent can be used. In addition, a material liquid that forms a charge transfer layer in a short process can be prepared by using a first organic solvent.

For example, formation of the charge transfer layer involves the formation of a charge transfer layer by discharging the material liquid onto a desired region on the substrate by a liquid droplet jetting method followed by solidifying the material liquid on the substrate.

The release layer is formed with resin, for example, and is preferably formed with wax.

A method for manufacturing an organic EL display device according to an aspect of the invention includes: forming a charge transfer layer using organic compound particles or a material liquid formed according to the method for manufacturing organic compound particles for forming a charge transfer element or the method for manufacturing a material liquid for forming a charge transfer element. According to this method, a charge transfer layer having satisfactory characteristics can be formed easily due to particle leafing effects.

8. Organic compound particles according to an aspect of the present invention are organic compound particles formed by micro-fragmenting a laminate layer, containing a release layer and an organic compound layer having charge transferability, after separating the same from a base material on which the laminate layer is formed, wherein each of the particles is in the form of leaves (or scales). According to this configuration, the resulting material is satisfactory for forming a charge transfer element.

The release layer is formed with resin, for example, and is preferably formed with wax.

The material liquid according to an aspect of the invention contains the organic compound particles. According to this configuration, the resulting material is satisfactory for forming a charge transfer element.

An organic EL display device according to an aspect of the invention has a charge transfer layer formed by solidifying the material liquid. According to this configuration, a charge transfer layer having satisfactory characteristics is easily formed due to leafing effects of the particles.

For example, the molecular weight of the organic compound in the charge transfer layer is 1000 or less. The use of a low molecular weight material resistant to dissolution (or dispersal) in organic solvent in this manner improves the characteristics of the device.

### BRIEF DESCRIPTION OF THE DRAWINGS

FIG. 1 shows a cross-sectional view of a first step of a first embodiment;

FIG. 2 shows a cross-sectional view of a step for manufacturing an organic EL display device;

FIG. 3 shows a cross-sectional view of a first step of a second embodiment;

FIG. 4 shows a cross-sectional view of an ultrasonic pulverizing device for separating and micro-fragmenting a luminous layer formed on a sheet-like base material 1 in a liquid;

FIG. 5 shows a cross-sectional view of a first step of a third embodiment; and

FIG. 6 shows a cross-sectional view of steps for manufacturing an organic EL display device.

### DESCRIPTION OF EXEMPLARY EMBODIMENTS

### First Embodiment

A method for manufacturing an organic EL display device of the present embodiment has the following first to fourth steps. Among these, the first and second steps correspond to steps for manufacturing luminous element particles (composite luminous element particles), the third step for manufacturing an ink (material liquid), and the fourth step for manufacturing an organic EL display device.

First Step

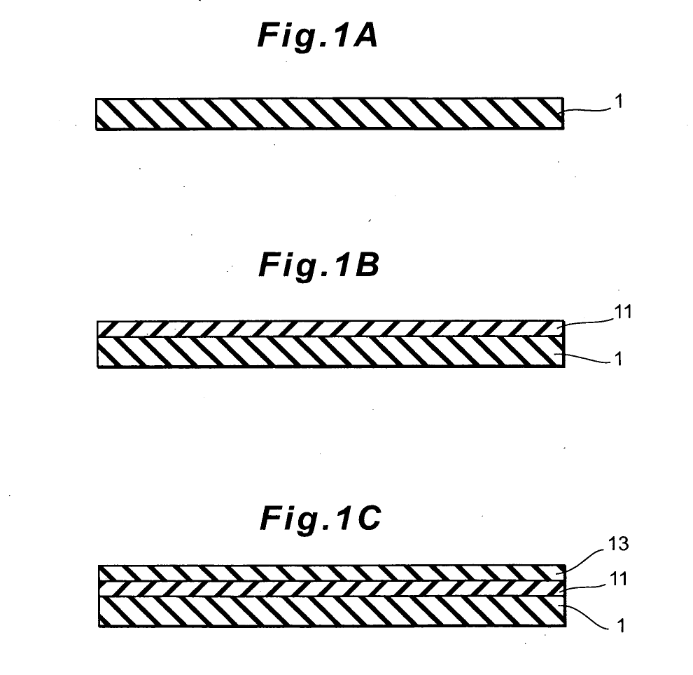

FIG. 1 shows a cross-sectional view of a first step of the present embodiment. As shown in FIGS. 1A to 1C, a luminous element layer at least including a release layer 11 and a luminous organic compound layer 13 is formed on a sheet-like base material 1.

Sheet-Like Base Material

There are no particular limitations on the sheet-like base material 1 used in this step, examples of which include polyester films such as polytetrafluoroethylene, polyethylene, polypropylene, polyethylene terephthalate or polyethylene naphthalate, polyamide films such as Nylon 66 or Nylon 6, and mold release films such as polycarbonate film, triacetate film or polyimide film.

Preferable examples of sheet-like base material 1 include polyethylene terephthalate and copolymers thereof.

There are no particular limitations on the thickness of these sheet-like base materials 1, and is preferably 10 to 150 μm. If the thickness of the sheet-like base material is 10 μm or more, there are no problems with handling during processing, and if 150 μm or less, there is ample flexibility and there are noproblems with rolling or separation.

### Release Layer

The release layer 11 used in this step is an undercoating layer of the luminous organic compound layer 13 to be described later, and is a layer for improving the releasability of luminous organic compound layer 13 from one side of sheet-like base material 1. Thus, there are no particular limitations on the material of this release layer, and various types or resins, such as resins readily soluble in water or organic solvents, and more specifically, cellulose derivatives, polyvinyl alcohol, polyethylene glycol, polyacrylic acid, polyacrylamide, polyvinylbutyral, acrylic acid copolymers or modified Nylon resins, are used preferably.

Release layer 11 is formed by typically used gravure coating, roll coating, blade coating, extrusion coating, dip coating or spin coating. The surface may be smoothened by calendaring treatment as necessary following coating and drying. In this case, the coating liquid can also contain an additive such as a viscosity regulator.

There are no particular limitations on the thickness of release layer 11 and is preferably within the range of 0.5 to 50 μm. If the thickness is less than 0.5 μm, mechanical strength becomes inadequate, while if the thickness exceeds 50 μm, subsequent separation and micro-fragmentation treatment become difficult due to excessively high strength.

Luminous Organic Compound Layer

The luminous organic compound layer 13 used in this step uses a fluorescent material or phosphorescent material for the luminous organic compound, and a phosphorescent material is particularly preferable in terms of luminous efficiency. In addition, a low material weight material, such as a material having a molecular weight of 1000 or less, is preferable in terms of luminous efficiency and service life.

Specific examples of luminous organic compounds include the organic compounds indicated below (chemical structural formulas (1) to (19)). One type of these compounds can be used or two or more types can be used as a mixture.

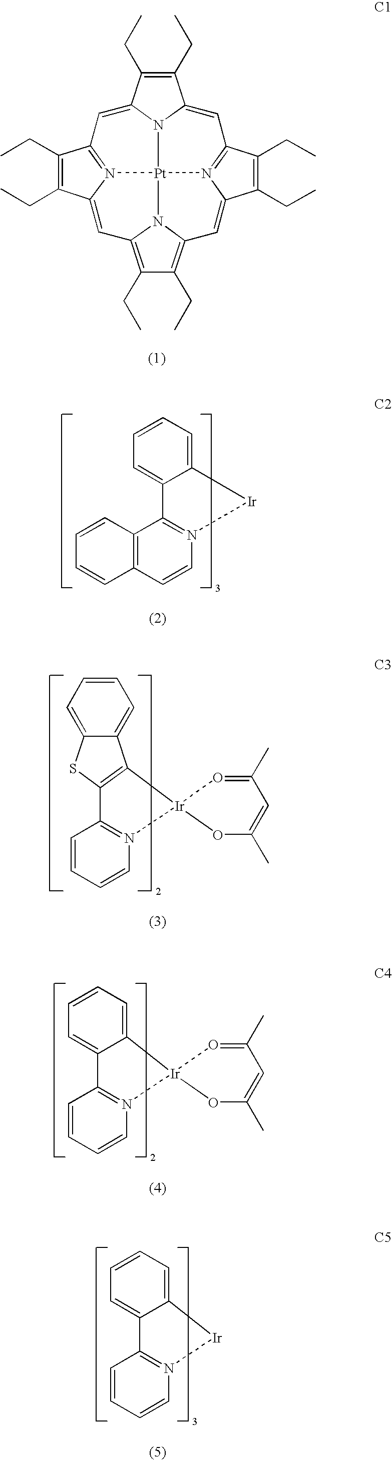

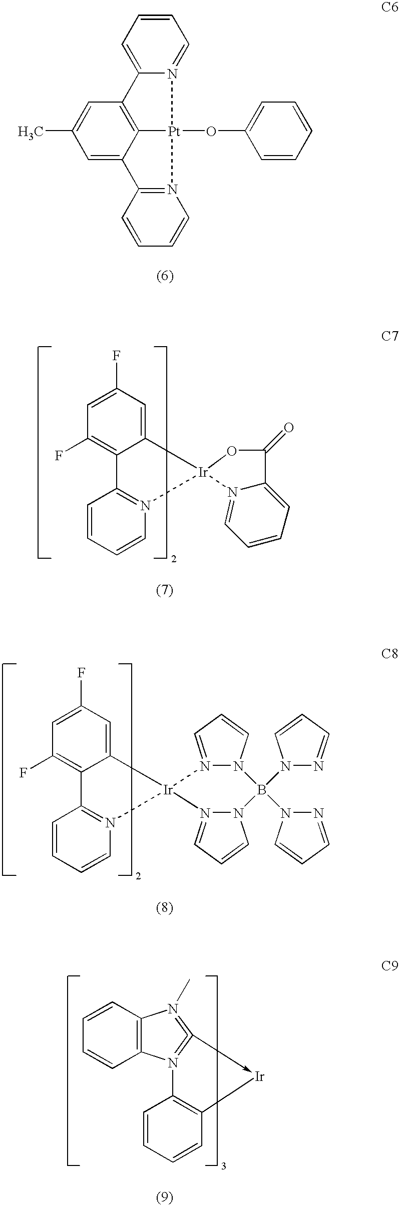

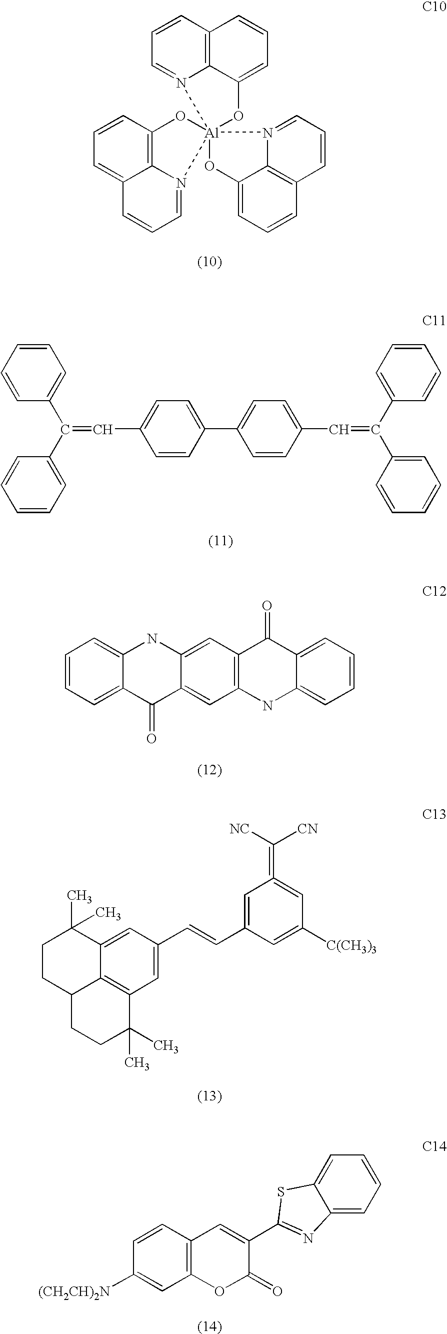

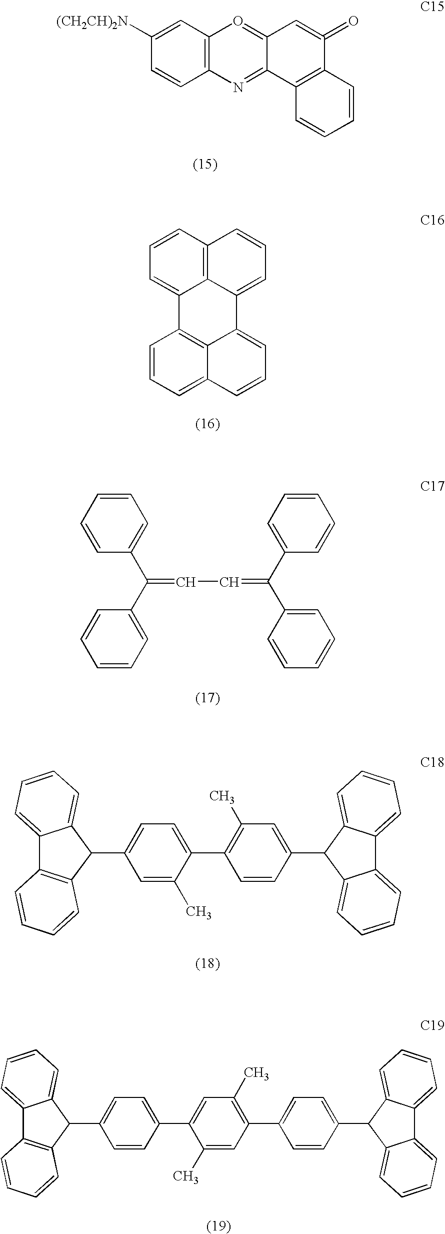

These organic compounds (luminous materials) are deposited on one side of sheet-like base material 1 on which the release layer has been formed by placing in a vacuum chamber and sublimating and evaporating by resistance heating (FIG. 1C). Luminous organic compound layer 13 is preferably formed by this type of so-called vacuum deposition. Examples of other deposition methods include ion plating and sputtering.

In addition, the thickness of luminous organic compound layer 13 is preferably 5 to 200 nm and more preferably 10 to 100 nm.

These steps by which is formed a luminous element layer at least formed of release layer 11 and luminous organic compound layer 13 are referred to as a first step.

Second Step

In this step, a luminous element layer formed of release layer 11 and luminous organic compound layer 13 formed in the first step is separated from sheet-like base material 1 using release layer 11 as the boundary of that separation followed by micro-fragmentation thereof to obtain luminous element particles.

There are no particular limitations on the separation and micro-fragmentation methods, examples of which include a method in which the luminous element layer is mechanically stripped off with a spatula-shaped member in the manner of a squeegee, a method in which the luminous element layer is immersed in an organic solvent (release solution) to dissolve release layer 11 and allow the luminous element layer to be lifted off followed by micro-fragmentation (leafing), and a method in which ultrasonic treatment is carried out simultaneous to immersing in an organic solvent (release solution) to promote micro-fragmentation. A sand mill, atomizer or nanomizer and the like may also be used to promote micro-fragmentation.

In addition, treatment may also be carried out by which the resulting luminous element particles are washed with an organic solvent to remove resin adhered to the particles.

These steps by which luminous element particles are manufactured by separating a luminous element layer from sheet-like base material 1 are referred to as a second step.

Third Step

In this step, luminous element particles obtained in the second step are dispersed in a dispersion medium to prepare a dispersion. Luminous element particles formed by mechanically stripping with the squeegee and the like are added to a dispersion medium. In addition, in the case of separating the luminous element layer from the sheet-like base material in a liquid in the second step together with micro-fragmenting by ultrasonic treatment and the like, the liquid may be used for the dispersion. Moreover, treatment may also be carried out by removing coarse particles by subjecting the dispersion to suitable filtration or centrifugal separation to narrow the particle size distribution.

The mean particle diameter of the luminous element particles is preferably such that the 50% volume average particle diameter thereof is about 0.05 to 3 μm as measured with a particle size distribution analyzer using dynamic light scattering as exemplified by a member of the NanoTrack UPA Series (Microtrack). The 50% volume average particle diameter refers to, in the case of assuming a single aggregation of particles and determining the particle size distribution thereof, the particle diameter at which a cumulative curve, when that curve is determined based on a value of 100% for the total volume of the aggregation of particles, reaches a predetermined ratio (here, 50%).

In addition, dispersion treatment may also be carried out by adding a dispersant such as a surfactant or resin as necessary. In this case, the surfactant or resin serves as a protective colloid that is able to improve dispersion stability.

These steps for manufacturing a dispersion of luminous element particles by dispersing luminous element particles in a dispersion medium are referred to as a third step.

Here, in the case of carrying out the second step in a liquid, the third step can also be carried out simultaneous to the second step as previously described.

Fourth Step

In this step, an organic luminous layer of a predetermined shape is formed using an ink (material liquid, discharge liquid) containing at least a dispersion of luminous element particles manufactured according to the third step. This organic luminous layer can be formed by a method such as photolithography, screen printing or an inkjet method. The use of an inkjet method is particularly preferable since it is able to easily accommodate large substrates at low cost.

Here, pixels having an organic EL device are formed by discharging the ink from an inkjet head (liquid droplet discharge device). For example, at least one color of ink among the three primary colors of red, green and blue, or intermediate colors thereof, is discharged onto a predetermined region. Use of an inkjet method enables discharge onto a fine region to be carried out easily and in a short period of time, while also facilitating adjustment of the amount of discharged ink. Accordingly, film properties and color developing performance with respect to developed color balance, brightness and the like can be easily controlled as desired.

Although the dispersion of luminous element particles may be filled directly into an inkjet head and discharged onto a specific region for use as the ink, a moisture retention agent may be added to prevent drying and coagulation in the nozzle opening. Examples of moisture retention agents include polyvalent alcohols such as glycerin, diethylene glycol, triethylene glycol, polyethylene glycol or polyglycerol, and sugars such as maltitol, xylitol or sorbitol. In addition, one type of these moisture retention agents may be used or two or more types may be used as a mixture.

In addition, coating stabilizers such as resin emulsions, surfactants or leveling agents can also be added. In addition, pH adjusters, antiseptics or antirust agents and the like may also be added.

Although the following provides a more detailed explanation of the present embodiment using examples thereof, the scope of the invention is naturally not limited thereby.

### Example 1

### Preparation of Sheet-Like Base Material

A resin coating solution having the following composition was coated onto a PET (polyethylene terephthalate) film having a film thickness of 100 μm by spin coating followed by drying to form a release layer.

Resin Coating Solution

The composition of the resin coating solution is shown in Table 1. The term “wt %” indicates percent by weight.

TABLE 1

| | |
|---|---|
| Cellulose acetate butyrate | 5.0 wt % |
| (molecular weight: 16,000, butylation | |
| rate: 50 to 54%) | |
| Diethylene glycol diethyl ether | 95.0 wt % |

Coating Conditions

The resin coating solution indicated in Table 1 was coated onto the PET film under the following conditions and then dried to form release layer 11.

Coating conditions: Rotation for 10 seconds at 500 rpm followed by rotation for 30 seconds at 2,000 rpm

Drying conditions: 30 minutes at 100° C.

The thickness of release layer 11 formed under these conditions was 10 μm.

Formation of Luminous Organic Compound Layer

Various types of vapor deposition layers having a film thickness of about 20 nm (red, blue and green luminous organic compound layers 13) were formed on the release layer 11 using the materials shown in Table 2. The apparatus used for vapor deposition is indicated below. As shown in Table 2, red luminous organic compound layer 13 was deposited by vapor deposition using a material in which the compounds of chemical structural formulas (10) and (13) were mixed at a ratio of 98 wt % and 2 wt %, respectively. Blue luminous organic compound layer 13 was deposited using 100 wt % of the compound of chemical structural formula (II), and green luminous organic compound layer 13 was deposited by vapor deposition using a material in which the compounds of chemical structural formulas (10) and (12) were mixed at a ratio of 98.5 wt % and 1.5 wt %, respectively.

Apparatus: Model VE-1010 Vacuum Deposition System (Vacuum Device, Inc.)

TABLE 2

| Red | Blue | Green |
|---|---|---|
| Formula (10): 98 wt % | Formula (11): | Formula (10): 98.5 wt % |
| Formula (13): 2 wt % | 100 wt % | Formula (12): 1.5 wt % |

Manufacturing of Luminous Element Particle Containing Ink

A PET film (sheet-like base material 1) having a luminous element layer formed of release layer 11 and luminous organic compound layer 13 formed according to the method described above was immersed in diethylene glycol diethyl ether and subjected to ultrasonic waves to carry out separation and micro-fragmentation.

Moreover, an organic solvent was suitably added to obtain red, blue and green luminous element particle inks.

The composition of each luminous element particle-containing ink is shown in Table 3.

TABLE 3

| | |
|---|---|
| Luminous element particles | 20.0 wt % |
| Dipropylene glycol monomethyl ether | 20.0 wt % |
| Diethylene glycol diethyl ether | Remainder |

Step for Manufacturing Organic EL Display Device

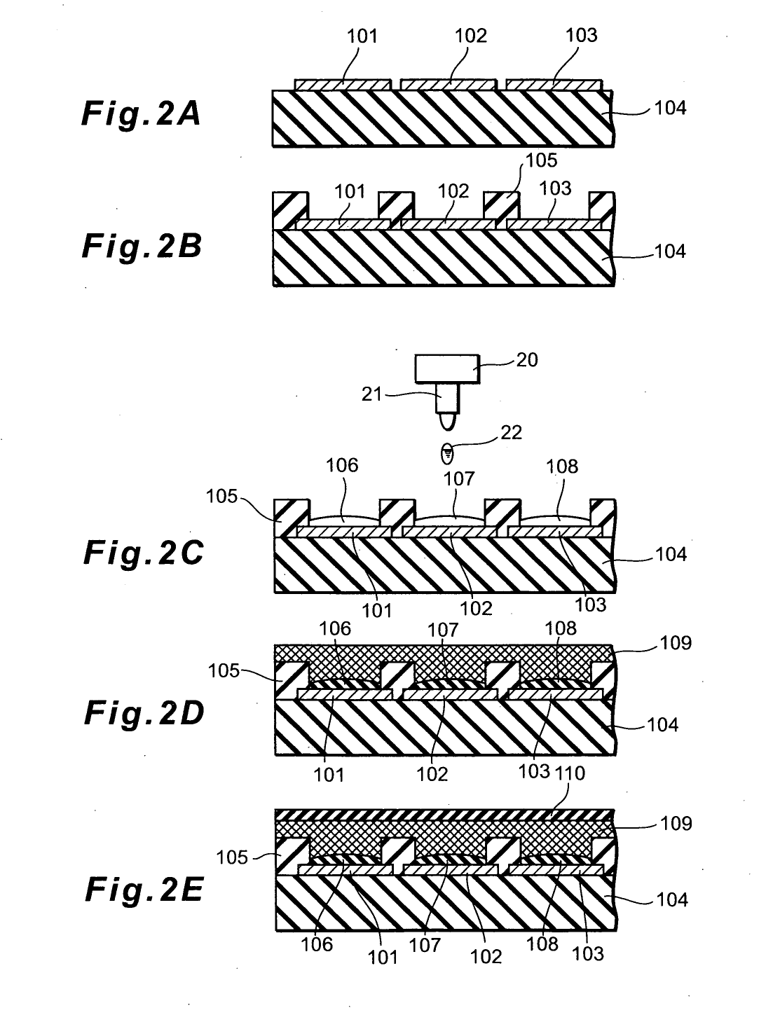

FIG. 2 shows a cross-sectional view of a step for manufacturing an organic EL display device. An organic EL display device was manufactured according to the steps shown in FIGS. 2A to 2E using the red, blue and green luminous element-containing inks as described above.

After forming an indium tin oxide (ITO) film over the entire surface of a glass substrate 104 at a film thickness of about 0.1 μm, an ITO transparent pixel electrode 101 for red pixels, transparent pixel electrode 102 for green pixels and transparent pixel electrode 103 for blue pixels were formed by patterning into squares measuring roughly 100 μm on a side by photolithography (FIG. 2A). Next, a black resin resist was coated onto these transparent pixel electrodes, and a black resin resist layer 105 was formed between the electrodes by photolithography (FIG. 2B) This black resin resist layer 105 is embedded between each transparent pixel electrode and serves as a light blocking layer and as a wall for preventing running of ink. This black resin resist layer 105 had a width of 20 μm and thickness of 2.0 μm.

Moreover, each color of ink 22 is discharged from an inkjet head 21 of an inkjet device 20 onto each desired region (FIG. 2C). Next, red organic luminous layer 106, green organic luminous layer 107 and blue organic luminous layer 108 were formed by heat-treating for 4 hours at 150° C. in a nitrogen atmosphere to remove the solvent in the ink.

Next, an electron transport layer 109 having a thickness of about 0.1 μm was formed by vacuum deposition of an undoped aluminum-quinolinole complex (FIG. 2D). This electron transport layer 109 facilitates injection of ions from a cathode, prevents electrode quenching by distancing the luminous portion from the cathode, and contributes to the formation of favorable contact with the cathode.

Finally, a counter electrode 110 in the form of an AlLi (alloy of aluminum and lithium) film having a thickness of 0.8 μm was formed on electron transport layer 109 (FIG. 2E). This counter electrode 110 also functions as a reflective sheet. An organic EL display device was manufactured by the steps described above.

### Example 2

### Preparation of Sheet-Like Base Material

A resin coating solution having the following composition was coated onto a PET film (sheet-like base material 1) having a film thickness of 100 μm by spin coating followed by drying to form release layer 11.

Resin Coating Solution

The composition of the resin coating solution is shown in Table 4.

TABLE 4

| | |
|---|---|
| PVA (polyvinyl alcohol, average molecular weight: | 3.0 wt % |
| 10,000, degree of saponification: 80%) | |
| N-methyl-2-pyrrolidone | 3.0 wt % |
| Isopropyl alcohol | Remainder |

Coating Conditions

The resin coating solution indicated in Table 4 was coated onto the PET film under the following conditions and then dried to form release layer 11.

Coating conditions: Rotation for 5 seconds at 500 rpm followed by rotation for 30 seconds at 2,000 rpm

Drying conditions: 30 minutes at 100° C.

The thickness of release layer 11 formed under these conditions was 8 μm.

Formation of Luminous Organic Compound Layer

Various types of vapor deposition layers having a film thickness of about 40 nm (red, blue and green luminous organic compound layers 13) were formed on the release layer 11 using the materials shown in Table 5. The apparatus used for vapor deposition is indicated below. As shown in Table 5, red luminous organic compound layer 13 was deposited by vapor deposition using a material in which the compounds of chemical structural formulas (18) and (3) were mixed at a ratio of 95 wt % and 5 wt %, respectively. Blue luminous organic compound layer 13 was deposited by vapor deposition using a material in which the compounds of chemical structural formulas (18) and (7) were mixed at a ratio of 92 wt % and 8 wt %, respectively. Green luminous organic compound layer 13 was deposited by vapor deposition using a material in which the compounds of chemical structural formulas (18) and (5) were mixed at a ratio of 95 wt % and 5 wt %, respectively.

Apparatus: Model VE-1010 Vacuum Deposition System (Vacuum Device, Inc.)

TABLE 5

| Red | Blue | Green |
|---|---|---|
| Formula (18): 95 wt % | Formula (18): 92 wt % | Formula (18): 95 wt % |
| Formula (3): 5 wt % | Formula (7): 8 wt % | Formula (5): 5 wt % |

Manufacturing of Luminous Element Particle-Containing Ink

A PET film (sheet-like base material 1) having a luminous element layer formed of release layer 11 and luminous organic compound layer 13 formed according to the method described above was stripped with a squeegee to obtain luminous element particles.

After washing the resulting luminous element particles with isopropyl alcohol, the luminous element particles were mixed with a dispersant, organic solvent and surfactant and then subjected to dispersion treatment for 2 hours together with glass beads (diameter: 1.7 mm, in an amount 1.5 times that of the mixture (based on weight)) using a sand mill (Yasukawa Seisakusho Co., Ltd.).

After removing the glass beads, centrifugal separation was carried out under the conditions indicated below to remove coarse particles. The resulting luminous element particles were added to a solvent in the form of the composition shown in Table 6 to obtain red, blue and green luminous element particle-containing inks.

Centrifugal separation conditions: 10,000 rpm×30 min

TABLE 6

| | |
|---|---|
| Luminous element particles | 10.0 wt % |
| HAS-1 | 5.0 wt % |
| (dispersant, alcoholic silica gel, Colcoat Co., Ltd.) | |
| N-methyl-2-pyrrolidone | 5.0 wt % |
| BYK-347 (surfactant, polysiloxane, BYK Co., Ltd.) | 0.5 wt % |
| Ultrapure water | Remainder |

Step for Manufacturing Organic EL Display Device

An organic EL display device was manufactured according to the steps shown in FIGS. 2A to 2E using the red, blue and green luminous element-containing inks as described above. After forming an ITO film over the entire surface of glass substrate 104 at a film thickness of about 0.1 μm, ITO transparent pixel electrode 101 for red pixels, transparent pixel electrode 102 for green pixels and transparent pixel electrode 103 for blue pixels were formed by patterning into squares measuring roughly 100 μm on a side by photolithography (FIG. 2A). Next, an α-NPD (N,N′-dinaphthyl-N,N′-diphenyl-4,4′-diaminobiphenyl) layer was formed by vacuum deposition on these transparent pixel electrodes to a thickness of about 0.05 μm to obtain a hole transport layer (not shown). Next, a black resin resist was coated onto the hole transport layer (transparent pixel electrodes), and black resin resist layer 105 was formed between the electrodes by photolithography (FIG. 2B). This black resin resist layer 105 is embedded between each transparent pixel electrode and serves as a light blocking layer and as a wall for preventing running of ink. This black resin resist layer 105 had a width of 20 μm and thickness of 2.0 μm.

Moreover, each color of ink 22 is discharged from inkjet head 21 of inkjet device 20 onto each desired region (FIG. 2C). Next, red organic luminous layer 106, green organic luminous layer 107 and blue organic luminous layer 108 were formed by heat-treating for 4 hours at 150° C. in a nitrogen atmosphere to remove the solvent in the ink.

Next, BCP (2,9-dimethyl-4,7-diphenyl-1,10-phenanthroline) was formed to a thickness of about 0.03 μm by vacuum deposition to obtain a hole blocking layer (not shown) for the purpose of preventing hole outflow. Moreover, an electron transport layer 109 having a thickness of 0.1 μm was formed by vacuum deposition of an undoped aluminum-quinolinole complex (FIG. 2D). This electron transport layer 109 facilitates injection of ions from a cathode, prevents electrode quenching by distancing the luminous portion from the cathode, and contributes to the formation of favorable contact with the cathode.

Finally, a counter electrode 110 in the form of an AlLi (alloy of aluminum and lithium) film having a thickness of 0.8 μm was formed on electron transport layer 109 (FIG. 2E). This counter electrode 110 also functions as a reflective sheet. An organic EL display device was manufactured by the steps described above.

### Example 3

### Preparation of Sheet-Like Base Material

A resin coating solution having the following composition was coated onto a PET film having a film thickness of 100 μm by spin coating followed by drying to form release layer 11.

Resin Coating Solution

The composition of the resin coating solution is shown in Table 4 as previously indicated.

Coating Conditions

The resin coating solution indicated in Table 4 was coated onto the PET film under the following conditions and then dried to form release layer.

Coating conditions: Rotation for 5 seconds at 500 rpm followed by rotation for 30 seconds at 2,000 rpm

Drying conditions: 30 minutes at 100° C.

The thickness of the release layer formed under these conditions was 8 μm.

Formation of Luminous Organic Compound Layer

Various types of vapor deposition layers having a film thickness of about 40 nm were formed on the release layer using the materials shown in Table 2 as previously indicated. The apparatus used for vapor deposition is indicated below.

Apparatus: Model VE-1010 Vacuum Deposition System (Vacuum Device, Inc.)

Manufacturing of Luminous Element Particle-Containing Ink

A PET film (sheet-like base material 1) having a luminous element layer formed of release layer 11 and luminous organic compound layer 13 formed according to the method described above was immersed in isopropyl alcohol and subjected to ultrasonic treatment to carry out separation and micro-fragmentation.

Moreover, an organic solvent was suitably added to obtain red, blue and green luminous element particle-containing inks.

The composition of each ink is shown in Table 7.

TABLE 7

| | |
|---|---|
| Luminous element particles | 2.0 wt % |
| N-methyl-2-pyrrolidone | 5.0 wt % |
| Isopropyl alcohol | 25.0 wt % |
| Ultrapure water | Remainder |

Step for Manufacturing Organic EL Display Device

An organic EL display device was manufactured according to the steps shown in FIGS. 2A to 2E using the red, blue and green luminous element-containing inks as described above. After forming an ITO film over the entire surface of glass substrate 104 at a film thickness of about 0.1 μm, ITO transparent pixel electrode 101 for red pixels, transparent pixel electrode 102 for green pixels and transparent pixel electrode 103 for blue pixels were formed by patterning into squares measuring roughly 100 μm on a side by photolithography (FIG. 2A). Next, an α-NPD layer was formed by vacuum deposition on these transparent pixel electrodes to a thickness of about 0.05 μm to obtain a hole transport layer (not shown). Next, a black resin resist was coated onto the hole transport layer (transparent pixel electrodes), and black resin resist layer 105 was formed between the electrodes by photolithography (FIG. 2B). This black resin resist layer 105 is embedded between each transparent pixel electrode and serves as a light blocking layer and as a wall for preventing running of ink. This black resin resist layer 105 had a width of 20 μm and thickness of 2.0 μm.

Moreover, each color of ink 22 is discharged from inkjet head 21 of inkjet device 20 onto each desired region (FIG. 2C). Next, red organic luminous layer 106, green organic luminous layer 107 and blue organic luminous layer 108 were formed by heat-treating for 4 hours at 150° C. in a nitrogen atmosphere to remove the solvent in the ink.

Next, BCP (2,9-dimethyl-4,7-diphenyl-1,10-phenanthroline) was formed to a thickness of about 0.03 μm by vacuum deposition to obtain a hole blocking layer (not shown) for the purpose of preventing hole outflow. Moreover, an electron transport layer 109 having a thickness of about 0.1 μm was formed by vacuum deposition of an undoped aluminum-quinolinole complex (FIG. 2D). This electron transport layer 109 facilitates injection of ions from a cathode, prevents electrode quenching by distancing the luminous portion from the cathode, and contributes to the formation of favorable contact with the cathode.

Finally, a counter electrode 110 in the form of an AlLi film having a thickness of 0.8 μm was formed on electron transport layer 109 (FIG. 2E). This counter electrode 110 also functions as a reflective sheet. An organic EL display device was manufactured by the steps described above.

Evaluation

The luminous characteristics of the organic EL display devices produced in Examples 1 to 3 were evaluated for service life by assigning a value of 100% to initial brightness following stabilization treatment, applying a constant current with a standard waveform, continuously causing the display device to emit light, measuring the change in brightness, and measuring the time until brightness decreased to 50% of initial brightness for use as an indicator of luminous service life.

Those results are shown in Table 8. Examples 1 and 3 were able to be confirmed to have a service life in excess of 10,000 hours.

TABLE 8

| Example | Luminous service life (hr) |
|---|---|
| 1 | >10,000 |
| 2 | 200 to 500 |
| 3 | >10,000 |

In this manner, according to the method for manufacturing an organic EL display device as described above, in addition to being able to shorten the process and simplify equipment, the utilization efficiency of expensive organic material can be improved by a factor of two or more. Namely, in the case of forming a luminous organic compound layer of a desired shape by vapor deposition and photolithography, utilization efficiency decreases since a deposited film is formed at locations where it is not required. In contrast, in the method described above, manufacturing costs can also be reduced.

In addition, according to the method for manufacturing an organic EL display device as described above, even low molecular weight compounds can be formed into particles, thereby improving the dispersibility of the particles for use as an ink. Namely, although comparatively high molecular weight compounds can be dispersed in various solvents, low molecular weight compounds have been difficult to use as ink due to poor solubility and dispersibility. Accordingly, although it was difficult to take advantage of the characteristics of low molecular weight luminous organic compounds in the form of satisfactory developed color balance, brightness and long service life, according to the above method, film properties and color development performance with respect to developed color balance, brightness and the like can be easily controlled as desired.

Accordingly, an organic EL display device using luminous element particles as described above has a broad color expression range as well as satisfactory device characteristics such as enabling a long service life.

### Second Embodiment

The method for manufacturing an organic EL display device of this embodiment has the following first to fifth steps. Among these, the first and second steps are for producing luminous element particles, the third and fourth steps are for manufacturing ink (material liquid), and the fifth step corresponds to a step for producing an organic EL display device. In the present embodiment, a wax layer 11A is used for the release layer explained in the first embodiment.

First Step

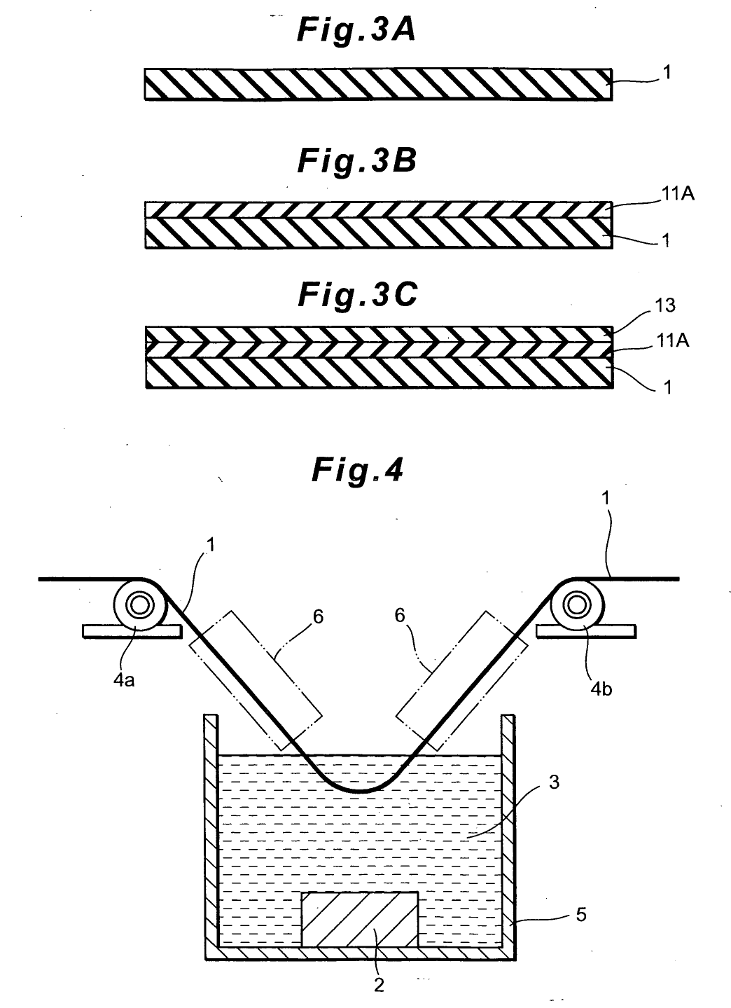

FIG. 3 shows a cross-sectional view of a first step of the present embodiment. As shown in FIGS. 3A to 3C, a luminous element layer at least having a wax layer 11A and a luminous organic compound layer 13 is formed on a sheet-like base material 1.

Sheet-Like Base Material

There are no particular limitations on the sheet-like base material 1 used in this step, examples of which include polyester films such as polytetrafluoroethylene, polyethylene, polypropylene, polyethylene terephthalate or polyethylene naphthalate, polyamide films such as Nylon 66 or Nylon 6, and mold release films such as polycarbonate film, triacetate film or polyimide film.

Preferable examples of sheet-like base material 1 include polyethylene terephthalate and copolymers thereof.

There are no particular limitations on the thickness of these sheet-like base materials 1, and is preferably 10 to 150 μm. If the thickness of the sheet-like base material is 10 μm or more, there are no problems with handling during processing, and if 150 μm or less, there is ample flexibility and there are no problems with rolling or separation.

Wax Layer (Release Layer)

The wax layer 11A used in this step is an undercoating layer of the luminous organic compound layer 13 to be described later, and is a layer for improving the releasability of luminous organic compound layer 13 from one side of sheet-like base material 1. In addition, as will be explained in detail forthwith, in an organic EL display device, it is preferable to reduce the amount of release layer material remaining in an organic luminous layer as much as possible to improve the luminous performance of that organic luminous layer. Consequently, although a resin material readily soluble in water or organic solvent such as the cellulose derivatives and the like explained in the first embodiment may be used for the release layer, use of the wax materials indicated below for the resin makes it possible to reduce the amount of release layer material remaining in the organic luminous layer.

There are no particular limitations on the wax material, and any wax material can be used provided it is a solid at normal temperatures, preferable examples of which include tricosanone, heptacosanone, 1-hexadecanol, 1-octadecanol, 1,2-decanediol, 1,10-decanediol, 1,12-dodecanediol, 2-isopropyl-5-methylcyclohexanol, monolaurin, monostearin, monoolein, acetoamide, lauric amide, stearic amide and oleic amide. More preferable examples include waxes readily soluble in water or organic solvent, waxes having a comparatively low melting point of 40 to 150° C., and sublimatible waxes easily vaporized by heating.

Wax layer 11A is formed by typically used gravure coating, roll coating, blade coating, extrusion coating, dip coating or spin coating. The surface may be smoothened by calendaring treatment as necessary following coating and drying. In this case, the coating liquid can also contain an additive such as a viscosity regulator.

There are no particular limitations on the thickness of wax layer 11A and is preferably within the range of 0.5 to 50 μm. If the thickness is less than 0.5 μm, mechanical strength becomes inadequate, while if the thickness exceeds 50 μm, subsequent separation and micro-fragmentation treatment become difficult due to excessively high strength.

Luminous Organic Compound Layer

The luminous organic compound layer 13 used in this step uses a fluorescent material or phosphorescent material for the luminous organic compound, and a phosphorescent material is particularly preferable in terms of luminous efficiency. In addition, a low material weight material, such as a material having a molecular weight of 1000 or less, is preferable in terms of luminous efficiency and service life.

Specific examples of luminous organic compounds include the organic compounds indicated in the first embodiment (chemical structural formulas (1) to (19)). One type of these compounds can be used or two or more types can be used as a mixture.

These organic compounds (luminous materials) are deposited on one side of sheet-like base material 1 on which the wax layer 11A has been formed by placing in a vacuum chamber and sublimating and evaporating by resistance heating (FIG. 3C). Luminous organic compound layer 13 is preferably formed by this type of so-called vacuum deposition. Examples of other deposition methods include ion plating and sputtering.

In addition, the thickness of luminous organic compound layer 13 is preferably 5 to 200 nm and more preferably 10 to 100 nm.

These steps by which is formed a luminous element layer at least formed of wax layer 11A and luminous organic compound layer 13 are referred to as a first step.

Second Step

In this step, a luminous element layer formed of wax layer 11A and luminous organic compound layer 13 formed in the first step is separated from sheet-like base material 1 using wax layer 11A as the boundary of that separation followed by micro-fragmentation thereof to obtain luminous element particles.

There are no particular limitations on the separation and micro-fragmentation methods, examples of which include a method in which the luminous element layer is mechanically stripped off with a spatula-shaped member in the manner of a squeegee, a method in which the luminous element layer is immersed in an organic solvent (release solution) to dissolve wax layer 11A and allow the luminous element layer to be lifted off followed by micro-fragmentation (leafing), and a method in which ultrasonic treatment is carried out simultaneous to immersing in an organic solvent (release solution) to promote micro-fragmentation. A sand mill, atomizer or nanomizer and the like may also be used to promote micro-fragmentation.

In addition, treatment may also be carried out by which the resulting luminous element particles are washed with an organic solvent to remove wax adhered to the particles.

The following provides a specific explanation of an ultrasonic pulverizing device. FIG. 4 shows a cross-sectional view of an ultrasonic pulverizing device for separating and pulverizing a luminous layer formed on sheet-like base material 1 in a liquid. Furthermore, in FIG. 4, a description of the luminous element layer (wax layer 11A and luminous organic compound layer 13) on the sheet-like base material 1 is omitted.

As shown in the drawing, this device is provided with a tank 5, which is filled with an organic solvent (release solution) for separating the luminous element layer, and an ultrasonic vibration unit 2 arranged in the bottom of tank 5. The frequency of the applied ultrasonic waves is 38 KHz. Moreover, this device has sheet transport mechanisms 4a and 4b, these mechanisms support sheet-like base material 1 so as to be immersed in organic solvent (release solution) between 2a and 2b. Moreover, these mechanisms are configured so as to transport sheet-like base material 1 at a predetermined speed and tension. Immersed surface area, speed, tension and the like are preferably adjusted so that ultrasonic waves are efficiently supplied to the luminous element layer. In addition, sheet supporting units 6 may also be provided for transporting the luminous element layer without causing damage thereto even in the case of having formed luminous element layers on both sides of sheet-like base material 1 for the purpose of improving production efficiency. For example, sheet supporting units 6 may be provided that transport in a predetermined direction while retaining both sides of sheet-like base material 1. These sheet supporting units 6 are also configured so as to provide a speed adjustment function and tension adjustment function. In addition, these transport mechanisms may be configured to allow transport in both directions in order to transport sheet-like base material 1 through the liquid a plurality of times as necessary.

A sheet-like base material 1 on which a luminous element layer has been formed is placed in this ultrasonic pulverizing device while applying ultrasonic waves, after which the sheet-like base material 1 is sequentially immersed in an organic solvent (release solution) 3. In this immersion unit, wax layer 11A dissolves, luminous organic compound layer 13 of the layer there above partially separates, and leaf-like (or scale-like) luminous element particles are suspended in the organic solvent (release solution) 3. Furthermore, the wax layer 11A is not required to be completely dissolved, but rather may only be dissolved to an extent to which separation progresses.

A plurality of luminous element particles are obtained in the form of an aggregate by carrying out ultrafiltration treatment on the liquid following this separation and micro-fragmentation treatment. In addition, wax layer 11A adhered to the particles may be removed by washing with organic solvent following filtration and aggregation. In addition, treatment for narrowing the size distribution of the particles may also be carried out by settling and removing coarse particles by centrifugal separation.

These steps by which luminous element particles are manufactured by separating a luminous element layer from sheet-like base material 1 are referred to as a second step.

Third Step

In this step, luminous element particles obtained in the second step are dispersed in a dispersion medium to prepare a dispersion. Luminous element particles formed by mechanically stripping with a squeegee and the like as described above are added to a dispersion medium. In addition, in the case of having carried out separation and micro-fragmentation in a liquid, the dispersion medium is added to the filtered aggregate or centrifuged supernatant. Here, the dispersion medium primarily consists of organic solvent. A dispersant is preferably added as necessary. Examples of dispersants used include surfactants and resins. In this case, the surfactant or resin serves as a protective colloid that improves dispersion stability.

The luminous element particles are in the form of leaves as previously described. The thickness of the leaf-like luminous element particles is preferably 5 to 200 nm and more preferably 10 to 100 nm. In addition, the mean particle diameter of the luminous element particles is preferably such that the 50% volume average particle diameter thereof is about 0.05 to 3 μm as measured by dynamic light scattering. An example of particle size distribution analyzer able to be used is a member of the NanoTrack UPA Series (Microtrack). Furthermore, the 50% volume average particle diameter refers to, in the case of assuming a single aggregation of particles and determining the particle size distribution thereof, the particle diameter at which a cumulative curve, when that curve is determined based on a value of 100% for the total volume of the aggregation of particles, reaches a predetermined ratio (here, 50%).

The steps for manufacturing a dispersion of luminous element particles as described above are referred to as a third step.

Here, in the case the organic solvent (release solution) used in the second step also serves as a dispersion, the dispersion can be obtained in the second step. Namely, the solution following separation and micro-fragmentation treatment can be used as a dispersion. In this case, a dispersant (such as a surfactant or resin) may be added as necessary. In this manner, using the liquid obtained in the second step (organic solvent 3 in FIG. 4) directly in this step makes it possible to stabilize the dispersion of luminous element particles in a short process.

Fourth Step

In this step, an ink (material liquid, discharge liquid) is prepared using a dispersion of luminous element particles formed in the third step. A high-performance organic luminous layer can be easily formed with a simple device in the manner of a spin coating device or inkjet device by preparing the ink using various types of additives.

In the case of using an inkjet method in particular, various types of additives (adjusters) are preferably added to adjust physical properties over a wide range, including viscosity, surface tension, contact angle between the substrate and discharge liquid, and dynamic properties accompanying the solvent evaporation process. For example, a resin emulsion, surfactant or leveling agent may be added as a coating stabilizer. In addition, a pH adjuster, antiseptic or antirust agent may also be added.

Here, selection of the organic solvent (release solution, dispersion medium) used in the second and third steps, as well as ink adjusters used in this step, is particularly important. Examples of solvents include water and/or organic solvents such as ethylene glycol, ethylene glycol monoethyl ether, ethylene glycol diethyl ether, ethylene glycol monobutyl ether, ethylene glycol monobutyl ether acetate, diethylene glycol, diethylene glycol monoethyl ether, diethylene glycol diethyl ether, diethylene glycol monobutyl ether, diethylene glycol monobutyl ether acetate, triethylene glycol, triethylene glycol monoethyl ether, triethylene glycol diethyl ether, triethylene glycol monobutyl ether, triethylene glycol monobutyl ether acetate, propylene glycol monomethyl ether, propylene glycol n-propyl ether, propylene glycol n-butyl ether, propylene glycol monomethyl ether acetate, dipropylene glycol monomethyl ether, tripropylene glycol n-butyl ether, tetraethylene glycol dimethyl ether, tetraethylene glycol monobutyl ether, 1,3-butylene glycol, 1,3-butylene glycol diacetate, 2-pyrrolidone, N-methyl-2-pyrrolidone or γ-butyrolactone. Organic solvents having a vapor pressure at 20° C. of 0.01 to 20 mmHg are more preferable. In the case of using an organic solvent having an excessively low vapor pressure, it becomes difficult to obtain desired luminous performance due to increased susceptibility of the organic solvent remaining in the organic luminous layer. Conversely, in the case of using an organic solvent having an excessively high vapor pressure, it becomes difficult to obtain a stable discharge of ink from the ink nozzle due to large changes in concentration and viscosity caused by volatilization, particularly in the case of using an inkjet method.

The concentration of luminous element particles in the ink is preferably 1 to 30 wt % and more preferably 2 to 20 wt %.

This step for preparing an ink having a preferable composition for forming an organic luminous layer of a predetermined shape by a liquid process at least containing a dispersion of luminous element particles is referred to as a fourth step.

Fifth Step

In this step, an organic luminous layer of a predetermined shape is formed using the ink manufactured in the above steps. This step is referred to as a fifth step. The organic luminous layer can be formed by a method such as spin coating, photolithography, screen printing or an inkjet method. The use of an inkjet method is particularly preferable since it is able to easily accommodate large substrates at low cost.

Here, an organic luminous layer having pixels of an organic EL device are formed by discharging the ink from an inkjet head (liquid droplet discharge device). For example, at least one color of ink among the three primary colors of red, green and blue, or intermediate colors thereof, is discharged onto a predetermined region. Use of an inkjet method enables discharge onto a fine region to be carried out easily and in a short period of time, while also facilitating adjustment of the amount of discharged ink. Accordingly, color developing performance with respect to film properties such as film shape and film thickness, developed color balance, brightness and the like can be easily controlled as desired.

Next, a discharge liquid of a predetermined shape is subjected to heat treatment and dried (solidified) to form an organic luminous layer. At this time, heat treatment is preferably carried out to an extent that volatilizes impurities such as wax components remaining in the layer.

In addition to drying (solidifying) the discharge liquid by subjecting to heat treatment, impurities such as wax components and dispersion medium remaining in the organic luminous layer, surf actant or resin and the like contained in these liquids, and resin emulsion, surfactant, leveling agent or organic solvent and the like used to prepare the ink, can be volatilized. As a result, the adhesion between luminous organic compounds (between particles) is improved thereby making it possible to improve luminous performance.

Although heat treatment is ordinarily carried out in air, it can also be carried out in an inert gas atmosphere such as nitrogen, argon or helium as necessary. The temperature of heat treatment is 50° C. or higher, preferably 150° C. or higher and more preferably 250° C. or higher. In addition, volatilization of the impurities can be promoted by heating under reduced pressure. Accordingly, treatment can be carried out at a low temperature and in a short period of time. In addition, heat treatment may be carried out two or more times. In addition, there are no particular limitations on the duration of heat treatment (total duration when carrying out multiple times), and is preferably from 5 minutes to 5 hours.

Although the following provides a more detailed explanation of the present embodiment through examples thereof, the scope of the invention is naturally not limited thereby.

### Example 4

### Preparation of Sheet-Like Base Material

Acetoamide (sublimatible wax component) melted at 80° C. was coated onto a PET film having a film thickness of 100 μm by roll coating followed by drying to form a wax layer 11A. The thickness of wax layer 11A formed under these conditions was 5 μm.

Formation of Luminous Organic Compound Layer

Vapor deposition layers having a film thickness of about 10 nm (red, blue and green luminous organic compound layers 13) were formed on the wax layer 11A using the materials shown in Table 9. The apparatus used for vapor deposition is indicated below. As shown in Table 9, red luminous organic compound layer 13 was deposited by vapor deposition using a material in which the compounds of chemical structural formulas (10) and (13) were mixed at a ratio of 98 wt % and 2 wt %, respectively. Blue luminous organic compound layer 13 was deposited by vapor deposition of a material formed of 100 wt % of the compound of chemical structural formula (10) or (11). Green luminous organic compound layer 13 was deposited by vapor deposition using a material in which the compounds of chemical structural formulas (11) and (13) were mixed at a ratio of 98 wt % and 2 wt %, respectively.

Apparatus: Model VE-1010 Vacuum Deposition System (Vacuum Device, Inc.)

TABLE 9

| Red | Blue | Green |
|---|---|---|
| Formula (10): 98 wt % | Formula (10): 100 wt % | Formula (11): 98 wt % |
| Formula (13): 2 wt % | or | Formula (13): 2 wt % |
| | Formula (11): 100 wt % | |

Manufacturing or Luminous Element Particle-Containing Ink

A PET film (sheet-like base material 1) having a luminous element layer formed of wax layer 11A and luminous organic compound layers 13 formed according to the method described above was placed in the ultrasonic pulverizing device shown in FIG. 4, immersed in diethylene glycol diethyl ether and subjected to ultrasonic waves to carry out separation and micro-fragmentation.

Dipropylene glycol monomethyl ether was added to the diethylene glycol diethyl ether following separation and micro-fragmentation to prepare red, blue and green inks. Red, blue and green luminous element particles were respectively dispersed in each ink.

The composition of each ink is shown in Table 10.

TABLE 10

| | |
|---|---|
| Luminous element particles | 20.0 wt % |
| Dipropylene glycol monomethyl ether | 20.0 wt % |
| Diethylene glycol diethyl ether | Remainder |

Step for Manufacturing Organic EL Display Device

An organic EL display device was manufactured using the red, blue and green luminous element particle-containing inks described above. Since the process for manufacturing the organic EL display device of this example is the same as that shown in FIG. 2, an explanation is provided with reference to FIG. 2.

After forming an ITO film over the entire surface of a glass substrate 104 at a film thickness of about 0.1 μm, an ITO transparent pixel electrode 101 for red pixels, transparent pixel electrode 102 for green pixels and transparent pixel electrode 103 for blue pixels were formed by patterning into squares measuring roughly 100 μm on a side by photolithography (FIG. 2A). Next, a black resin resist was coated onto these transparent pixel electrodes, and a black resin resist layer 105 was formed between the electrodes by photolithography (FIG. 2B). This black resin resist layer 105 is embedded between each transparent pixel electrode and serves as a light blocking layer and as a wall for preventing running of ink. This black resin resist layer 105 had a width of 20 μm and thickness of 2.0 μm.

Moreover, each color of ink 22 is discharged from an inkjet head 21 of an inkjet device 20 onto each desired region (FIG. 2C). Next, red organic luminous layer 106, green organic luminous layer 107 and blue organic luminous layer 108 were formed by heat-treating for 4 hours at 150° C. in a nitrogen atmosphere to remove the solvent in the ink.

Next, an electron transport layer 109 having a thickness of about 0.1 μm was formed by vacuum deposition of an undoped aluminum-quinolinole complex (FIG. 2D). This electron transport layer 109 facilitates injection of ions from a cathode, prevents electrode quenching by distancing the luminous portion from the cathode, and contributes to the formation of favorable contact with the cathode.

Finally, a counter electrode 110 in the form of an AlLi film having a thickness of 0.8 μm was formed on electron transport layer 109 (FIG. 2E). This counter electrode 110 also functions as a reflective sheet. An organic EL display device was manufactured by the steps described above.

### Example 5

### Preparation of Sheet-Like Base Material

A wax coating solution having the following composition was coated onto a PET film (sheet-like base material 1) having a thickness of 50 μm by spin coating followed by drying to form wax layer 11A.

The composition of the wax coating solution is shown in Table 11.

TABLE 11

| | |
|---|---|
| 1,10-decanediol (wax component) | 3.0 wt % |
| γ-butyrolactone | 5.0 wt % |
| Isopropyl alcohol | Remainder |

Coating Conditions

The wax coating solution indicated in Table 11 was coated onto the PET film (sheet-like base material 1) under the following conditions and then dried to form wax layer 11A.

Coating conditions: Rotation for 5 seconds at 500 rpm followed by rotation for 30 seconds at 2,000 rpm

Drying conditions: 30 minutes at 50° C.

The thickness of wax layer 11A formed under these conditions was 8 μm.

Formation of Luminous Organic Compound Layer

Vapor deposition layers having a film thickness of about 30 nm (red, blue and green luminous organic compound layers) were formed on the wax layer 11A using the materials shown in Table 12. The apparatus used for vapor deposition is indicated below. As shown in Table 12, red luminous organic compound layer 13 was deposited by vapor deposition using a material in which the compounds of chemical structural formulas (18) and (3) were mixed at a ratio of 95 wt % and 5 wt %, respectively. Blue luminous organic compound layer 13 was deposited by vapor deposition of a material formed of 100 wt % of the compound of chemical structural formula (3), (7) or (18). Green luminous organic compound layer 13 was deposited by vapor deposition using a material in which the compounds of chemical structural formulas (18) and (7) were mixed at a ratio of 95 wt % and 5 wt %, respectively.

Apparatus: Model VE-1010 Vacuum Deposition System (Vacuum Device, Inc.)

TABLE 12

| Red | Blue | Green |
|---|---|---|
| Formula (18): 95 wt % | Formula (3): 100 wt % | Formula (18): 95 wt % |
| Formula (3): 5 wt % | or | Formula (7): 5 wt % |
| | Formula (7): 100 wt % | |
| | or | |
| | Formula (18): 100 wt % | |

Manufacturing of Luminous Element Particle-Containing Ink

A PET film (sheet-like base material 1) having a luminous element layer formed of wax layer 11A and luminous organic compound layers 13 formed according to the method described above was stripped off with a squeegee to obtain luminous element particles.

After washing the resulting luminous element particles with isopropyl alcohol, a suitable organic solvent was added followed by subjecting to dispersion treatment for 2 hours together with glass beads (diameter: 1.7 mm, in an amount 1.5 times that of the mixture (based on weight)) using a sand mill (Yasukawa Seisakusho Co., Ltd.).

After removing the glass beads, centrifugal separation was carried out under the conditions indicated below to remove coarse particles. The resulting luminous element particles were added to a solvent in the form of the composition shown in Table 13 to obtain red, blue and green inks.

Centrifugal separation conditions: 10,000 rpm×30 min The composition of each ink is shown in Table 13.

TABLE 13

| | |
|---|---|
| Luminous element particles | 1.5 wt % |
| γ-butyrolactone | 10.0 wt % |
| Isopropyl alcohol | 5.0 wt % |
| Ultrapure water | Remainder |

Step for Manufacturing Organic EL Display Device

An organic EL display device was manufactured using the above inks. Since the process for manufacturing the organic EL display device of this example is the same as that shown in FIG. 2, an explanation is provided with reference to FIG. 2.

After forming an ITO film over the entire surface of glass substrate 104 at a film thickness of about 0.1 μm, an ITO transparent pixel electrode 101 for red pixels, transparent pixel electrode 102 for green pixels and transparent pixel electrode 103 for blue pixels were formed by patterning into squares measuring roughly 100 μm on a side by photolithography (FIG. 2A). Next, a black resin resist was coated onto these transparent pixel electrodes, and black resin resist layer 105 was formed between the electrodes by photolithography (FIG. 2B). This black resin resist layer 105 is embedded between each transparent pixel electrode and serves as a light blocking layer and as a wall for preventing running of ink. This black resin resist layer 105 had a width of 20 μm and thickness of 2.0 μm.

Moreover, each red, blue and green ink 22 is discharged from inkjet head 21 of inkjet device 20 onto each desired region (FIG. 2C). Next, red organic luminous layer 106, green organic luminous layer 107 and blue organic luminous layer 108 were formed by heat-treating for 4 hours at 150° C. in a nitrogen atmosphere to remove the solvent in the ink.

Next, BCP was formed to a thickness of about 0.03 μm by vacuum deposition to obtain a hole blocking layer (not shown) for the purpose of preventing hole outflow. Moreover, electron transport layer 109 having a thickness of about 0.1 μm was formed by vacuum deposition of an undoped aluminum-quinolinole complex (FIG. 2D). This electron transport layer 109 facilitates injection of ions from a cathode, prevents electrode quenching by distancing the luminous portion from the cathode, and contributes to the formation of favorable contact with the cathode.

Finally, a counter electrode 110 in the form of an AlLi film having a thickness of 0.8 μm was formed on electron transport layer 109 (FIG. 2E). This counter electrode 110 also functions as a reflective sheet. An organic EL display device was manufactured by the steps described above.

### Example 6

### Preparation of Sheet-Like Base Material

2-isopropyl-5-methylcyclohexanol (sublimatible wax component) melted at 50° C. was coated onto a PET film having a film thickness of 100 μm by spin coating followed by drying to form wax layer 11A. The thickness of wax layer 11A formed under these conditions was 5 μm.

Formation of Luminous Organic Compound Layer

Vapor deposition layers having a film thickness of about 10 nm (red, blue and green luminous organic compound layers) were formed on the wax layer 11A using the materials shown in Table 14. The apparatus used for vapor deposition is indicated below. As shown in Table 14, red luminous organic compound layer was deposited by vapor deposition using a material in which the compounds of chemical structural formulas (10) and (13) were mixed at a ratio of 98 wt % and 2 wt %, respectively. Blue luminous organic compound layer 13 was deposited by vapor deposition of a material formed of 100 wt % of the compound of chemical structural formula (10) or (11). Green luminous organic compound layer 13 was deposited by vapor deposition using a material in which the compounds of chemical structural formulas (11) and (13) were mixed at a ratio of 98 wt % and 2 wt %, respectively.

Apparatus: Model VE-1010 Vacuum Deposition System (Vacuum Device, Inc.)

TABLE 14

| Red | Blue | Green |
|---|---|---|
| Formula (10): 98 wt % | Formula (10): 100 wt % | Formula (11): 98 wt % |
| Formula (13): 2 wt % | or | Formula (13): 2 wt % |
| | Formula (11): 100 wt % | |

Manufacturing of Luminous Element Particle-Containing Ink

A PET film (sheet-like base material 1) having a luminous element layer formed of wax layer 11A and luminous organic compound layers formed according to the method described above was placed in the ultrasonic pulverizing device shown in FIG. 4, immersed in dipropylene glycol monomethyl ether and subjected to ultrasonic waves to carry out separation and micro-fragmentation.

Dipropylene glycol monomethyl ether was added to ultrapure water following the separation and micro-fragmentation to prepare red, blue and green inks. Red, blue and green luminous element particles were respectively dispersed in each ink.

The composition of each ink is shown in Table 15.

TABLE 15

| | |
|---|---|
| Luminous element particles | 20.0 wt % |
| Dipropylene glycol monomethyl ether | 50.0 wt % |
| Ultrapure water | Remainder |

Step for Manufacturing Organic EL Display Device

An organic EL display device was manufactured using the red, blue and green inks described above. The process for manufacturing the organic EL display device of this example is the same as that of Example 4 of the present embodiment.

Namely, after forming transparent pixel electrodes and black resin resist layer 105 on glass substrate 104, each color of ink (dispersions of luminous element particles for red, blue and green ink) 22 is discharged from inkjet head 21 of inkjet device 20 onto each desired region (FIGS. 2A to 2C). Next, red organic luminous layer 106, green organic luminous layer 107 and blue organic luminous layer 108 were formed by heat-treating for 3 hours at 200° C. in a nitrogen atmosphere to remove the solvent in the ink.

Next, electron transport layer 109 having a thickness of about 0.1 μm was formed by vacuum deposition of an undoped aluminum-quinolinole complex (FIG. 2D). Finally, counter electrode 110 in the form of an AlLi film having a thickness of 0.8 μm was formed by vapor deposition (FIG. 2E). An organic EL display device was manufactured by the steps described above.

Evaluation

The luminous characteristics of the organic EL display devices produced in Examples 4 to 6 were evaluated for service life. The organic EL display devices were evaluated by assigning a value of 100% to initial brightness following stabilization treatment, applying a constant current with a standard waveform, continuously causing the display devices to emit light, measuring the change in brightness, and measuring the time until brightness decreased to 50% of initial brightness for use as an indicator of luminous service life.

Those results are shown in Table 16. Examples 4 to 6 were able to be confirmed to have a service life in excess of 15,000 hours.

In addition, with respect to initial brightness, the mean brightness of red, green and blue was 800 cd/m² in Example 4, 1200 cd/m² in Example 5 and 1100 cd/m² in Example 6.

TABLE 16

| Example | Luminous service life (hr) |
|---|---|
| 4 | >15,000 |
| 5 | >15,000 |
| 6 | >15,000 |

In this manner, according to the method for manufacturing an organic EL display device as described above, in addition to being able to shorten the process and simplify equipment, the utilization efficiency of expensive organic material can be improved by a factor of two or more. Namely, in the case of forming a luminous organic compound layer of a desired shape by vapor deposition and photolithography, utilization efficiency decreases since a deposited film is formed at locations where it is not required. In contrast, in the method described above, manufacturing costs can also be reduced.

In addition, according to the method for manufacturing an organic EL display device as described above, even low molecular weight compounds can be formed into particles, thereby improving the dispersibility of the particles for use as an ink. Namely, although comparatively high molecular weight compounds can be dispersed in various solvents, low molecular weight compounds have been difficult to use as ink due to poor solubility and dispersibility. Accordingly, although it was difficult to take advantage of the characteristics of low molecular weight luminous organic compounds in the form of satisfactory developed color balance, brightness and long service life, according to the above method, film properties and color development performance with respect to developed color balance, brightness and the like can be easily controlled as desired.

Accordingly, an organic EL display device using luminous element particles as described above has a broad color expression range as well as satisfactory device characteristics such as enabling a long service life.

### Third Embodiment

The method for manufacturing an organic EL display device of this embodiment has the following first to fifth steps. Among these, the first and second steps are for producing organic compound particles for forming a charge transfer element, the third and fourth steps are for manufacturing ink (material liquid), and the fifth step corresponds to a step for producing an organic EL display device.

First Step

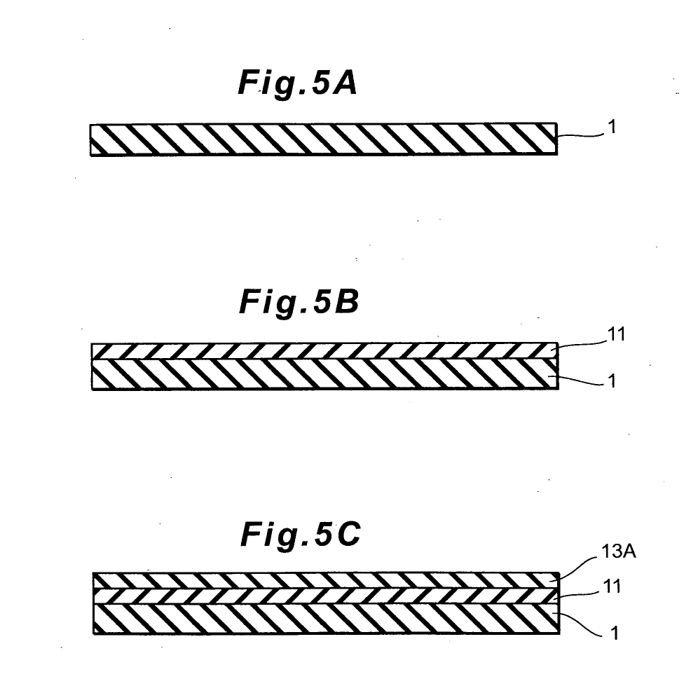

FIG. 5 shows a cross-sectional view of a first step of the present embodiment. As shown in FIGS. 5A to 5C, a laminate layer at least having a release layer 11 and a charge transfer material layer (organic compound layer having charge transferability) 13A is formed on a sheet-like base material 1. Here, the charge transfer material layer 13A refers to a layer serving as a material for forming a charge transfer layer of an organic EL display device to be described later. A hole transfer layer and electron transfer layer are contained in this charge transfer layer. In addition, a hole injection layer and a hole transport layer are contained in the hole transfer layer, and an electron injection layer and electron transport layer are contained in the electron transfer layer. Although the injection layers and transport layers are used with the same meanings, in the case of composing by layering transfer layers, the layer in contact with an electrode may be referred to as an injection layer while the remaining layers may be referred to as transport layers in order to distinguish between the two.

Sheet-Like Base Material

There are no particular limitations on the sheet-like base material 1 used in this step, examples of which include polyester films such as polytetrafluoroethylene, polyethylene, polypropylene, polyethylene terephthalate or polyethylene naphthalate, polyamide films such as Nylon 66 or Nylon 6, and mold release films such as polycarbonate film, triacetate film or polyimide film.

Preferable examples of sheet-like base material 1 include polyethylene terephthalate and copolymers thereof.

There are no particular limitations on the thickness of these sheet-like base materials 1, and is preferably 10 to 150 μm. If the thickness of the sheet-like base material is 10 μm or more, there are no problems with handling during processing, and if 150 μm or less, there is ample flexibility and there are no problems with rolling or separation.

Release Layer

The release layer 11 used in this step is an undercoating layer of a charge transfer material layer 13A to be described later, and is a layer for improving the releasability of charge transfer material layer 13A from one side of sheet-like base material 1. There are no particular limitations on the material of this release layer, and various types or resins, such as resins readily soluble in water or organic solvents, and more specifically, cellulose derivatives, polyvinyl alcohol, polyethylene glycol, polyacrylic acid, polyacrylamide, polyvinylbutyral, acrylic acid copolymers or modified Nylon resins, are used preferably.

Release layer 11 is formed by typically used gravure coating, roll coating, blade coating, extrusion coating, dip coating or spin coating. The surface may be smoothened by calendaring treatment as necessary following coating and drying. In this case, the coating liquid can also contain an additive such as a viscosity regulator.

There are no particular limitations on the thickness of release layer 11 and is preferably within the range of 0.5 to 50 μm. If the thickness is less than 0.5 μm, mechanical strength becomes inadequate, while if the thickness exceeds 50 μm, subsequent separation and micro-fragmentation treatment become difficult due to excessively high strength.

Charge Transfer Material Layer

The following lists examples of compounds used as materials for forming the charge transfer material layer. Examples of hole transfer materials include low molecular weight phenylamine derivatives and phthalocyanine compounds such as TPB (tetra-N-phenylbenzidine) or TDAB (1,3,5-tris (diphenylaminobenzene)). In addition, examples of electron transfer materials include aluminum-quinolinole derivatives, oxadiazole derivatives, triazole derivatives, bathophenanthroline derivatives and silole derivatives.

Specific examples of hole transfer materials include those compounds represented by the following chemical structural formulas (20) to (30), while specific examples of electron transfer materials include those compounds represented by the following chemical structural formulas (31) to (37). One type of these compounds can be used or two or more types can be used as a mixture.

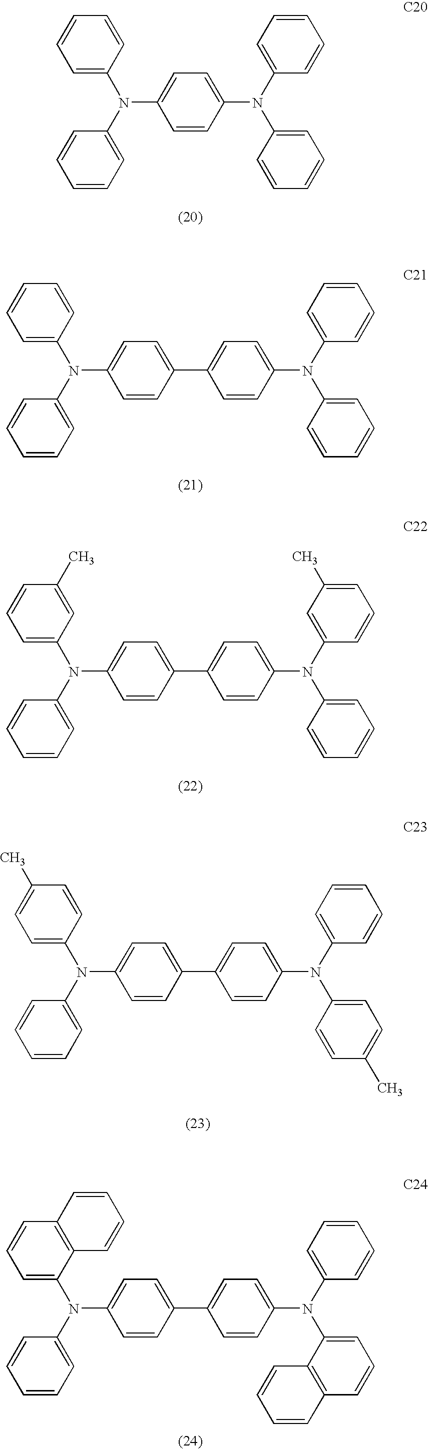

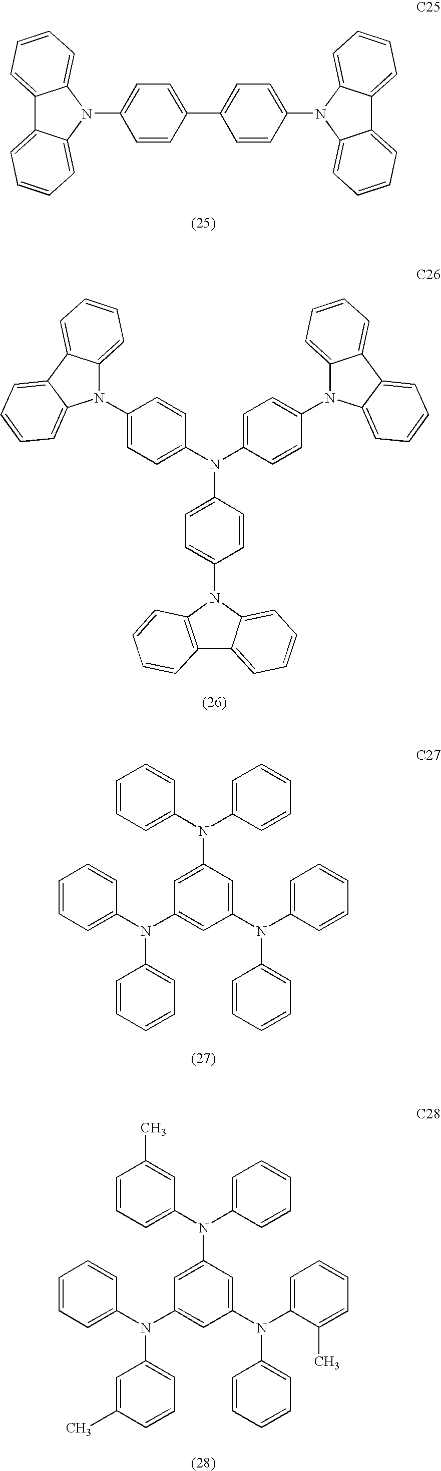

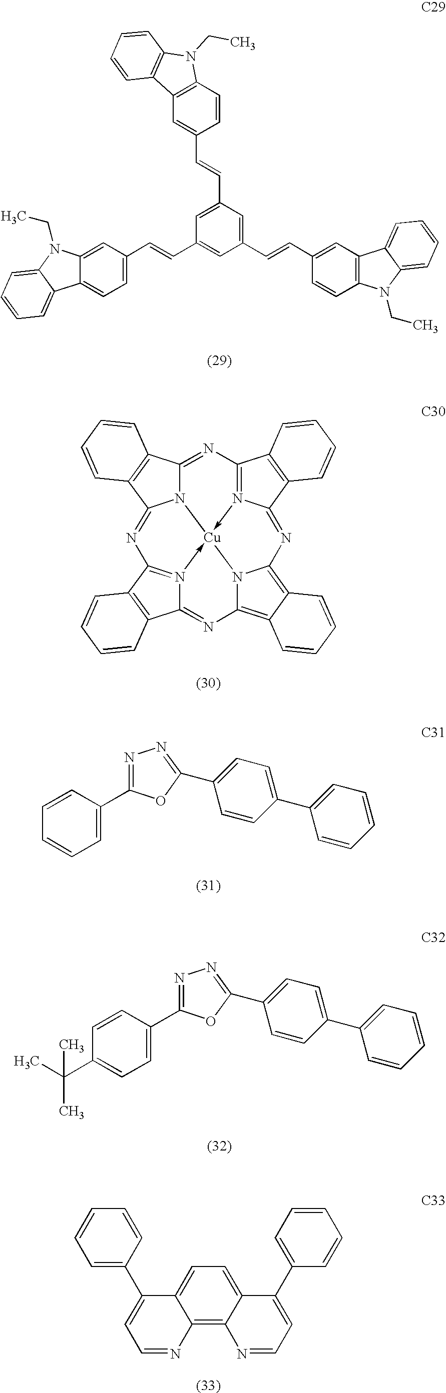

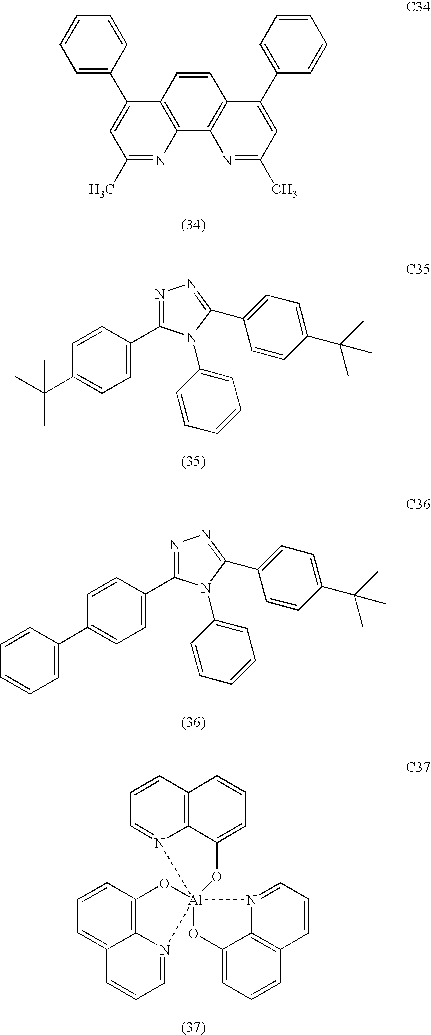

These organic compounds are deposited on one side of sheet-like base material 1 on which the release layer 11 has been formed by placing in a vacuum chamber and sublimating and evaporating by resistance heating (FIG. 5C). Charge transfer material layer 13A is preferably formed by this type of so-called vacuum deposition. Examples of other deposition methods include ion plating and sputtering.

In addition, the thickness of charge transfer material layer 13A is preferably 5 to 200 nm and more preferably 10 to 100 nm.

These steps by which is formed a laminate layer at least formed of release layer 11 and charge transfer material layer 13A are referred to as a first step.

Second Step

In this step, a laminate layer formed of release layer 11 and charge transfer material layer 13A formed in the first step is separated from sheet-like base material 1 using release layer 11 as the boundary of that separation followed by micro-fragmentation thereof to obtain transfer element particles (organic compound particles for forming a charge transfer element).

There are no particular limitations on the separation and micro-fragmentation methods, examples of which include a method in which the laminate layer is mechanically stripped off with a spatula-shaped member such as a squeegee, a method in which the laminate layer is immersed in an organic solvent (release solution) to dissolve release layer 11 and allow the laminate layer to be lifted off followed by micro-fragmentation (leafing), and a method in which ultrasonic treatment is carried out simultaneous to immersing in an organic solvent (release solution) to promote micro-fragmentation. A sand mill, atomizer or nanomizer and the like may also be used to promote micro-fragmentation.

In addition, treatment may also be carried out by which the resulting transfer element particles are washed with an organic solvent to remove resin adhered to the particles.

Here, a sheet-like base material 1 on which a laminate layer has been formed is placed in an ultrasonic pulverizing device as previously described (FIG. 4) while applying ultrasonic waves, after which the sheet-like base material 1 is sequentially immersed in an organic solvent (release solution) 3. In this immersion unit, release layer 11 dissolves, charge transfer material layer 13A of the layer there above partially separates, and leaf-like transfer element particles are suspended in the organic solvent (release solution) 3. A plurality of transfer element particles are obtained in the form of an aggregate by carrying out filtration treatment on the liquid following this separation and micro-fragmentation treatment. In addition, release layer 11 adhered to the particles may be removed by washing with organic solvent following filtration and aggregation. In addition, treatment for narrowing the size distribution of the particles may also be carried out by settling and removing coarse particles by centrifugal separation.

These steps by which transfer element particles are manufactured by separating a transfer element layer from sheet-like base material 1 are referred to as a second step.

Third Step

In this step, transfer element particles obtained in the second step are dispersed in a dispersion medium to prepare a dispersion. Transfer element particles formed by mechanically stripping with a squeegee and the like as described above are added to a dispersion medium. In addition, in the case of having carried out separation and micro-fragmentation in a liquid, the dispersion medium is added to the filtered solid or centrifuged supernatant. Here, the dispersion medium primarily consists of organic solvent. A dispersant is preferably added as necessary. Examples of dispersants used include surfactants and resins. In this case, the surfactant or resin serves as a protective colloid that improves dispersion stability.

The transfer element particles are in the form of leaves as previously described. The mean particle diameter of the transfer element particles is preferably such that the 50% volume average particle diameter thereof is about 0.05 to 3 μm as determined by dynamic light scattering. An example of particle size distribution analyzer able to be used is a member of the NanoTrack UPA Series (Microtrack). Furthermore, the 50% volume average particle diameter refers to, in the case of assuming a single aggregation of particles and determining the particle size distribution thereof, the particle diameter at which a cumulative curve, when that curve is determined based on a value of 100% for the total volume of the aggregation of particles, reaches a predetermined ratio (here, 50%).

The steps for manufacturing a dispersion of transfer element particles as described above are referred to as a third step.

Here, in the case the organic solvent (release solution) 3 used in the second step also serves as a dispersion, the dispersion can be obtained in the second step. Namely, the solution following separation and micro-fragmentation treatment can be used as a dispersion. In this case, a dispersant (such as a surfactant or resin) may be added as necessary. In this manner, using the liquid obtained in the second step (organic solvent 3 in FIG. 4) directly in this step makes it possible to stabilize the dispersion of transfer element particles in a short process.

Fourth Step

In this step, an ink (material liquid, discharge liquid) is prepared using a dispersion of transfer element particles formed in the third step. A high-performance charge transfer layer can be easily formed with a simple device in the manner of a spin coating device or inkjet device by preparing the ink using various types of additives.

In the case of using an inkjet method in particular, various types of additives (adjusters) are preferably added to adjust physical properties over a wide range, including viscosity, surface tension, contact angle between the substrate and discharge liquid, and dynamic properties accompanying the solvent evaporation process. For example, a moisture retention agent may be added for the purpose of preventing of drying or solidification in the nozzles. Examples of moisture retention agents used include polyvalent alcohols such as glycerin, diethylene glycol, triethylene glycol, polyethylene glycol or polyglycerol, and sugars such as maltitol, xylitol or sorbitol. In addition, a resin emulsion, surfactant or leveling agent may be added as a coating stabilizer. In addition, a pH adjuster, antiseptic or antirust agent may also be added.

Here, selection of the organic solvent (release solution, dispersion medium) used in the second and third steps, as well as ink adjusters used in this step, is particularly important. Examples of solvents include water and/or organic solvents such as the examples of organic solvents explained in the second embodiment ranging from ethylene glycol to γ-butyrolactone. Here, organic solvents having a vapor pressure at 20° C. of 0.01 to 20 mmHg are more preferable. In the case of using an organic solvent having an excessively low vapor pressure, it becomes difficult to obtain desired transfer performance due to increased susceptibility of the organic solvent remaining in the charge transfer layer. Conversely, in the case of using an organic solvent having an excessively high vapor pressure, it becomes difficult to obtain a stable discharge of ink from the ink nozzle due to large changes in concentration and viscosity caused by volatilization, particularly in the case of using an inkjet method.

The concentration of transfer element particles in the ink is preferably 1 to 30 wt % and more preferably 2 to 20 wt %.

This step for preparing an ink having a preferable composition for forming a charge transfer layer of a predetermined shape by a liquid process at least containing a dispersion of transfer element particles is referred to as a fourth step.

Fifth Step

In this step, a charge transfer layer of a predetermined shape is formed using the ink at least containing a dispersion of transfer element particles manufactured in the above steps. This step is referred to as a fifth step. The charge transfer layer can be formed by a method such as spin coating, photolithography, screen printing or an inkjet method. The use of an inkjet method is particularly preferable since it is able to easily accommodate large substrates at low cost.

Here, a charge transfer layer having pixels of an organic EL device are formed by discharging the ink from an inkjet head (liquid droplet discharge device). For example, the ink of a hole transfer layer or electron transfer layer is discharged onto a predetermined region. Use of an inkjet method enables discharge onto a fine region to be carried out easily and in a short period of time, while also facilitating adjustment of the amount of discharged ink.

Next, a discharge liquid of a predetermined shape is subjected to heat treatment and dried (solidified) to form a charge transfer layer (hole transfer layer or electron transfer layer). At this time, heat treatment is preferably carried out to an extent that volatilizes impurities such as resin components remaining in the layer.

In addition to drying (solidifying) the discharge liquid by subjecting to heat treatment, impurities such as resin components and dispersion medium remaining in the charge transfer layer, surfactant or resin and the like contained in these liquids, and resin emulsion, surfactant, leveling agent or organic solvent and the like used to prepare the ink, can be volatilized. As a result, the adhesion between transfer element particles is improved thereby making it possible to improve transfer performance.

Although heat treatment is ordinarily carried out in air, it can also be carried out in an inert gas atmosphere such as nitrogen, argon or helium as necessary. The temperature of heat treatment is 50° C. or higher, preferably 150° C. or higher and more preferably 250° C. or higher. In addition, volatilization of the impurities can be promoted by heating under reduced pressure. Accordingly, treatment can be carried out at a low temperature and in a short period of time. In addition, heat treatment may be carried out two or more times. In addition, there are no particular limitations on the duration of heat treatment (total duration when carrying out multiple times), and is preferably from 5 minutes to 5 hours.

Although the following provides a more detailed explanation of the present embodiment through examples thereof, the scope of the invention is naturally not limited thereby.

### Example 7

### Preparation of Sheet-Like Base Material

A resin coating solution having the following composition was coated onto a PET film (sheet-like base material 1) having a film thickness of 100 μm by spin coating followed by drying to form release layer 11.

Resin Coating Solution

The composition of the resin coating solution is shown in Table 17.

TABLE 17

| | |
|---|---|
| Cellulose acetate butyrate | 5.0 wt % |
| (molecular weight: 16,000, butylation rate: 50 to 54%) | |
| Diethylene glycol diethyl ether | 95.0 wt % |

Coating Conditions

The resin coating solution indicated in Table 17 was coated onto the PET film under the following conditions and then dried to form release layer 11.

Coating conditions: Rotation for 10 seconds at 500 rpm followed by rotation for 30 seconds at 2,000 rpm

Drying conditions: 30 minutes at 100° C.

The thickness of release layer 11 formed under these conditions was 10 μm.

Formation of Charge Transfer Material Layer

A vapor deposition layer (charge transfer material layer 13, and in this case, a hole transfer material layer) having a film thickness of about 15 nm was formed on release layer 11 using the material represented by chemical structural formula (24). The apparatus used for vapor deposition is indicated below.

Apparatus: Model VE-1010 Vacuum Deposition System (Vacuum Device, Inc.)

Manufacturing of Transfer Element Particle-Containing Ink

A PET film (sheet-like base material 1) having a laminate layer formed of release layer 11 and charge transfer material layer 13A formed according to the method described above was placed in the ultrasonic pulverizing device shown in FIG. 4, immersed in diethylene glycol diethyl ether and subjected to ultrasonic waves to carry out separation and micro-fragmentation.

Dipropylene glycol monomethyl ether was added to the diethylene glycol diethyl ether following the separation and micro-fragmentation treatment to prepare an ink. Transfer element particles were dispersed in the ink.

The composition of the ink is shown in Table 18.

TABLE 18

| | |
|---|---|
| Transfer element particles | 20.0 wt % |
| Dipropylene glycol monomethyl ether | 20.0 wt % |
| Diethylene glycol diethyl ether | Remainder |

Step for Manufacturing Organic EL Display Device

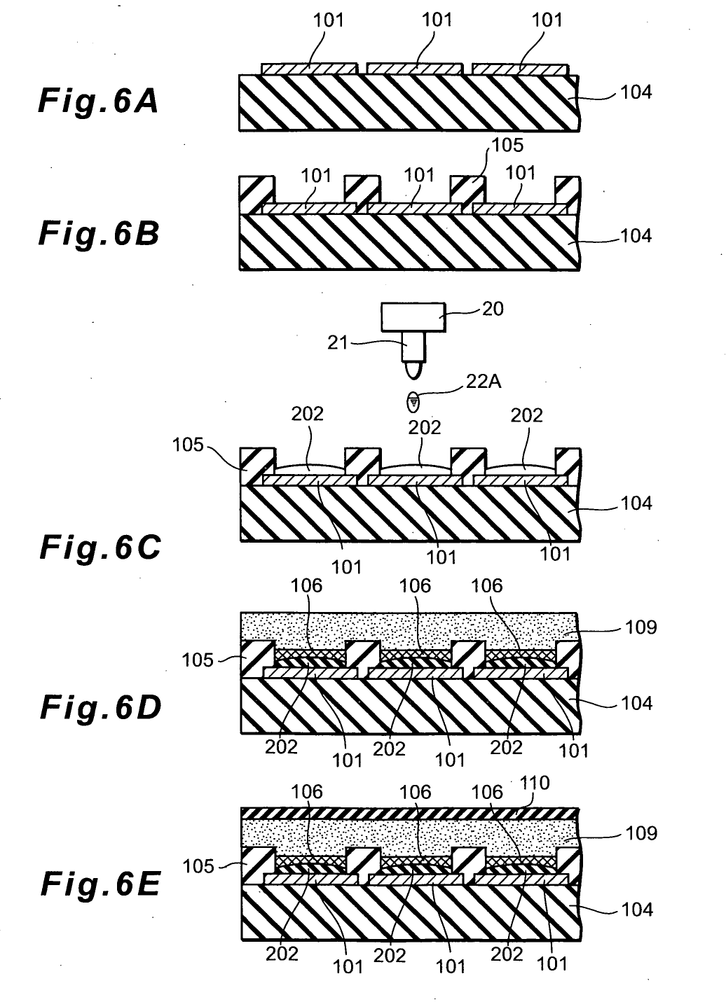

FIG. 6 shows a cross-sectional view of steps for manufacturing an organic EL display device. An organic EL display device was manufactured according to the steps shown in FIGS. 6A to 6E using the ink described above (Table 18).

After forming an ITO film over the entire surface of glass substrate 104 at a film thickness of about 0.1 μm, ITO transparent pixel electrodes 101 for red pixels were formed by patterning into squares measuring roughly 100 μm on a side by photolithography (FIG. 6A). Next, a black resin resist was coated onto the transparent pixel electrodes 101 and black resin resist layer 105 was formed between the electrodes by photolithography (FIG. 6B). This black resin resist layer 105 is embedded between the transparent pixel electrodes 101 and serves as a light blocking layer and as a wall for preventing running of ink. This black resin resist layer 105 had a width of 20 μm and thickness of 2.0 μm.

Next, ink 22A shown in Table 18 is discharged from inkjet head 21 of inkjet device 20 onto a desired region (FIG. 6C). Next, heat treatment was carried out and charge transfer layer (in this case, a hole transfer layer) 202 was formed having a thickness of about 0.1 μm.

Moreover, red organic luminous layer 106 having a thickness of about 0.1 μm was formed by vacuum deposition of a material having a mixture of the compounds represented by structural formulas (18) and (3) at a ratio of 95 wt % and 5 wt %, respectively.

Next, an electron transport layer 109 having a thickness of about 0.1 μm was formed by vacuum deposition of an undoped aluminum-quinolinole complex (FIG. 6D). This electron transport layer 109 facilitates injection of ions from a cathode, prevents electrode quenching by distancing the luminous portion from the cathode, and contributes to the formation of favorable contact with the cathode.

Finally, a counter electrode 110 in the form of an AlLi film having a thickness of 0.8 μm was formed on electron transport layer 109 (FIG. 6E). This counter electrode 110 also functions as a reflective sheet. An organic EL display device was manufactured by the steps described above.

### Example 8

### Preparation of Sheet-Like Base Material

A resin coating solution having the following composition was coated onto a PET film (sheet-like base material 1) having a film thickness of 100 μm by spin coating followed by drying to form release layer 11.

Resin Coating Solution

The composition of the resin coating solution is shown in Table 19.

TABLE 19

| | |
|---|---|
| PVA (polyvinyl alcohol, average molecular weight: | 3.0 wt % |
| 10,000, degree of saponification: 80%) | |
| N-methyl-2-pyrrolidone | 3.0 wt % |
| Isopropyl alcohol | Remainder |

Coating Conditions

The resin coating solution indicated in Table 19 was coated onto the PET film under the following conditions and then dried to form release layer 11.

Coating conditions: Rotation for 5 seconds at 500 rpm followed by rotation for 30 seconds at 2,000 rpm

Drying conditions: 30 minutes at 100° C.

The thickness of release layer 11 formed under these conditions was 8 μm.

Formation of Charge Transfer Material Layer

A vapor deposition layer (charge transfer material layer 13, and in this case, a hole transfer material layer) having a film thickness of about 10 nm was formed on release layer 11 using the material represented by chemical structural formula (27). The apparatus used for vapor deposition is indicated below.

Apparatus: Model VE-1010 Vacuum Deposition System (Vacuum Device, Inc.)

Manufacturing of Transfer Element Particle-Containing Ink

A PET film (sheet-like base material 1) having a laminate layer formed of release layer 11 and charge transfer material layer 13A formed according to the method described above was stripped off with a squeegee to obtain transfer element particles.

The resulting transfer element particles were further micro-fragmented using an ultrasonic pulverizing device to prepare an ink. The composition is shown in Table 20.

TABLE 20

| | |
|---|---|
| Transfer element particles | 20.0 wt % |
| Dipropylene glycol monomethyl ether | 20.0 wt % |
| Diethylene glycol diethyl ether | Remainder |

Step for Manufacturing Organic EL Display Device

ITO transparent pixel electrodes 101 for red pixels and black resin resist layer 105 were formed using the same process as Example 7 of the present embodiment (see FIG. 6). Next, ink 22A shown in Table 20 is discharged from inkjet head 21 of inkjet device 20 onto a desired region, heat treatment was carried out and hole transfer layer 202 was formed having a thickness of about 0.1 μm. Subsequently, red organic luminous layer 106 was formed using the same process as Example 7.

Next, BCP was formed to a thickness of about 0.03 μm by vacuum deposition to obtain a hole blocking layer (not shown) for the purpose of preventing hole outflow. Moreover, an electron transport layer 109 having a thickness of about 0.1 μm was formed by vacuum deposition of an undoped aluminum-quinolinole complex. This electron transport layer 109 facilitates injection of ions from a cathode, prevents electrode quenching by distancing the luminous portion from the cathode, and contributes to the formation of favorable contact with the cathode.

Finally, a counter electrode 110 in the form of an AlLi film having a thickness of 0.8 μm was formed on electron transport layer 109. This counter electrode 110 also functions as a reflective sheet. An organic EL display device was manufactured by the steps described above.

### Example 9

### Preparation of Sheet-Like Base Material

A resin coating solution having the following composition was coated onto a PET film (sheet-like base material 1) having a film thickness of 100 μm by spin coating followed by drying to form release layer 11.

Resin Coating Solution

The composition of the resin coating solution is shown in Table 21.

TABLE 21

| | |
|---|---|
| Cellulose acetate butyrate | 5.0 wt % |
| (molecular weight: 16,000, butylation rate: 50 to 54%) | |
| Diethylene glycol diethyl ether | 95.0 wt % |

Coating Conditions

The resin coating solution indicated in Table 21 was coated onto the PET film under the following conditions and then dried to form release layer 11.

Coating conditions: Rotation for 5 seconds at 500 rpm followed by rotation for 30 seconds at 2,000 rpm

Drying conditions: 30 minutes at 100° C.

The thickness of release layer 11 formed under these conditions was 10 μm.

Formation of Charge Transfer Material Layer

A vapor deposition layer (charge transfer material layer 13, and in this case, an electron transfer material layer) having a film thickness of about 10 nm was formed on release layer 11 using the material represented by chemical structural formula (31). The apparatus used for vapor deposition is indicated below.

Apparatus: Model VE-1010 Vacuum Deposition System (Vacuum Device, Inc.)

Manufacturing of Transfer Element Particle-Containing Ink

A PET film (sheet-like base material 1) having a laminate layer formed of release layer 11 and charge transfer material layer 13A formed according to the method described above was placed in the ultrasonic pulverizing device shown in FIG. 4, immersed in diethylene glycol diethyl ether and subjected to ultrasonic waves to carry out separation and micro-fragmentation.

Dipropylene glycol monomethyl ether was added to the diethylene glycol diethyl ether following the separation and micro-fragmentation treatment to prepare an ink. Transfer element particles were dispersed in the ink.

The composition of the ink is shown in Table 22.

TABLE 22

| | |
|---|---|
| Transfer element particles | 20.0 wt % |
| Dipropylene glycol monomethyl ether | 20.0 wt % |
| Diethylene glycol diethyl ether | Remainder |

Step for Manufacturing Organic EL Display Device

ITO-transparent pixel electrodes 101 for red pixels and black resin resist layer 105 were formed using the same process as Example 7 of the present embodiment (see FIG. 6). Next, a charge transfer layer (and in this case, a hole transfer layer) 202 was formed by vacuum deposition using the material represented by chemical structural formula (24). Moreover, red organic luminous layer 106 having a thickness of about 0.1 μm was formed by vacuum deposition of a material having a mixture of the compounds represented by structural formulas (18) and (3) at a ratio of 95 wt % and 5 wt %, respectively. Next, ink 22A shown in Table 22 was discharged from inkjet head 21 of inkjet device 20 onto red organic luminous layer 106, heat treatment was carried out and a charge transfer layer (in this case, electron transport layer 109) was formed having a thickness of about 0.1 μm (FIG. 6D). Finally, a counter electrode 110 in the form of an AlLi film having a thickness of 0.8 μm was formed on electron transport layer 109 (FIG. 6E). An organic EL display device was manufactured by the steps described above.

Evaluation

The luminous characteristics of the organic EL display devices produced in Examples 7 to 9 were evaluated for service life. The organic EL display devices were evaluated by assigning a value of 100% to initial brightness following stabilization treatment, applying a constant current with a standard waveform, continuously causing the display devices to emit light, measuring the change in brightness, and measuring the time until brightness decreased to 50% of initial brightness for use as an indicator of luminous service life.

As a result, Examples 7 to 9 were able to be confirmed to have a service life in excess of 10,000 hours.

In this manner, according to the method for manufacturing an organic EL display device as described above, in addition to being able to shorten the process and simplify equipment, the utilization efficiency of expensive organic material can be improved by a factor of two or more. Namely, in the case of forming a charge transfer layer of a desired shape by vapor deposition and photolithography, utilization efficiency decreases since a deposited film is formed at locations where it is not required. In contrast, in the method described above, manufacturing costs can also be reduced.

In addition, according to the method for manufacturing an organic EL display device as described above, even low molecular weight compounds can be formed into particles, thereby improving the dispersibility of the particles for use as an ink. Namely, although comparatively high molecular weight compounds can be dispersed in various solvents, low molecular weight compounds have been difficult to use as ink due to poor solubility and dispersibility. Accordingly, although it was difficult to take advantage of the characteristics of low molecular weight luminous organic compounds in the form of satisfactory developed color balance, brightness and long service life, according to the above method, a film having satisfactory characteristics and long service life can be formed.

In addition, the examples and application examples explained using the above-mentioned first to third embodiments can be suitably combined, altered or modified according to the application. The present invention is not limited to the descriptions of the embodiments as previously described.

For example, although a sheet-like base material was used in the first to third embodiments, other base materials may also be used. In addition, although only a red organic luminous layer was formed in the third embodiment, other colors of organic luminous layers may also be formed. In addition, each of the colors of ink explained in the first and second embodiments may be used at that time. In addition, although a resin material was used for the release layer in the third embodiment, a wax layer as explained in the second embodiment may also be used. In addition, although examples of organic EL display devices were explained in the first to third embodiments, the present invention is not limited to a display device, but rather can be broadly applied to devices such as illumination devices having a luminous layer or a charge transfer layer. In addition, the present invention is not limited to a luminous layer or charge transfer layer, but rather can also be applied to other organic layers (blocking layers) and the like including a device. In particular, the present invention is preferably applied to various types of organic layers used between electrodes.

What is claimed is:

1. A method for manufacturing luminous element particles, comprising:
forming a luminous element layer, containing a release layer and luminous organic compound layer, on at least one side of a base material; and
micro-fragmenting the luminous element layer after separating the same from the one side of the base material.

2. The method for manufacturing luminous element particles according to claim 1, wherein the release layer is a wax layer.

3. The method for manufacturing luminous element particles according to claim 1, wherein, the separation and the micro-fragmentation are carried out by applying ultrasonic waves to the luminous element layer by.

4. A method for manufacturing a material liquid for forming a luminous element, comprising:
forming a luminous element layer, containing a release layer and a luminous organic compound layer, on at least one side of a base material;
forming luminous element particles by micro-fragmenting the luminous element layer after separating the same from the one side of the base material; and
preparing a material liquid for forming a luminous element by adding a second organic solvent to the luminous element particles.

5. The method for manufacturing a material liquid for forming a luminous element according to claim 4, wherein the release layer is a wax layer.

6. A method for manufacturing an organic EL display device, comprising:
forming a luminous element layer, containing a release layer and a luminous organic compound layer, on at least one side of a base material;
forming luminous element particles by micro-fragmenting the luminous element layer after separating the same from the one side of the base material;
preparing a material liquid by adding a second organic solvent to the luminous element particles; and
forming a luminous layer by dropping the material liquid onto a substrate and solidifying thereon.

7. The method for manufacturing an organic EL display device according to claim 6, wherein, the micro-fragmentation is carried out while stripping off the luminous element layer.

8. A method for manufacturing an organic EL display device, comprising:
forming a luminous element layer, containing a release layer and a luminous organic compound layer, on at least one side of a sheet-like base material;
forming luminous element particles by immersing the sheet-like base material in a first organic solvent and occasionally separating a portion of the luminous organic compound layer from the release layer and micro-fragmenting the same;
preparing a material liquid using the first organic solvent containing the luminous element particles; and
forming a luminous layer by dropping the material liquid onto a substrate and solidifying thereon.

9. The method for manufacturing an organic EL display device according to claim 6, wherein, the formation of the luminous layer is carried out by discharging the material liquid onto a desired region on the substrate by a liquid droplet jetting method, followed by solidifying the material liquid on the substrate.

10. The method for manufacturing an organic EL display device according to claim 6, wherein the release layer is a wax layer.

11. A method for manufacturing an organic EL display device, comprising: forming a luminous layer using luminous element particles formed according to the method for manufacturing luminous element particles according to claim 1.

12. Luminous element particles formed by micro-fragmenting a Luminous element layer, containing a release layer and a luminous organic compound layer, after separating the same from a base material on which the luminous element layer is formed, wherein
each of the particles is in the form of leaves.

13. The luminous element particles according to claim 12, wherein the release layer is a wax layer.

14. A material liquid containing the luminous element particles according to claim 12.

15. An organic EL display device having a luminous layer formed by solidifying the material liquid according to claim 14.

16. The organic EL display device according to claim 15, wherein the molecular weight of the luminous organic compound in the luminous layer is 1,000 or less.

17. A method for manufacturing organic compound particles for forming a charge transfer element, comprising:
forming a laminate layer, containing a release layer and an organic compound layer having charge transferability, on at least one side of a base material; and
micro-fragmenting the laminate layer after separating the same from the one side of the base material.

18. The method for manufacturing organic compound particles for forming a charge transfer element according to claim 17, wherein the micro fragmentation is carried out by applying ultrasonic waves to the laminate layer.

19. The method for manufacturing organic compound particles for forming a charge transfer element according to claim 17, wherein the release layer is a wax layer.

20. A method for manufacturing a material liquid for forming a charge transfer element, comprising:
forming a laminate layer, containing a release layer and an organic compound layer having charge transferability, on at least one side of a base material;
forming organic compound particles by micro-fragmenting the laminate layer after separating the same from the one side of the base material; and
preparing a material liquid for forming a charge transfer element by adding a second solvent to the organic compound particles.

21. The method for manufacturing a material liquid for forming a charge transfer element according to claim 20, wherein the micro-fragmentation is carried out while stripping off the laminate layer.

22. The method for manufacturing a material liquid for forming a charge transfer element according to claim 20, wherein the release layer is a wax layer.

23. A method for manufacturing an organic EL display device, comprising:
forming a laminate layer, containing a release layer and an organic compound layer having charge transferability, on at least one side of a base material;
forming organic compound particles by micro-fragmenting the laminate layer after separating the same from the one side of the base material;
preparing a material liquid by adding a second organic solvent to the organic compound particles; and
forming a charge transfer layer by dropping the material liquid onto a substrate and solidifying thereon.

24. A method for manufacturing an organic EL display device, comprising:
forming a laminate layer, containing a release layer and an organic compound layer having charge transferability, on at least one side of a sheet-like base material;
forming organic compound particles by immersing the sheet-like base material in a first organic solvent and occasionally separating a portion of the organic compound layer from the release layer and micro-fragmenting the same;
preparing a material liquid using the first organic solvent containing the organic compound particles; and
forming a charge transfer layer by dropping the material liquid onto a substrate and solidifying thereon.

25. The method for manufacturing an organic EL display device according to claim 23, wherein the formation of the charge transfer layer is carried out by discharging the material liquid onto a desired region on the substrate by a liquid droplet jetting method, followed by solidifying the material liquid on the substrate.

26. The method for manufacturing an organic EL display device according to claim 23, wherein the release layer is a wax layer.

27. A method for manufacturing an organic EL display device, comprising: forming a charge transfer layer using a material liquid formed according to the method for manufacturing a material liquid for forming a charge transfer element according to claim 20.

28. Organic compound particles formed by micro-fragmenting a Laminate layer, containing a release layer and an organic compound layer having charge transferability, after separating the same from a base material on which the laminate layer is formed, wherein
each of the particles is in the form of leaves.

29. The organic compound particles according to claim 28, wherein the release layer is a wax layer.

30. A material liquid containing the organic compound particles according to claim 28.

31. An organic EL display device having a charge transfer layer formed by solidifying the material liquid according to claim 30.

32. The organic EL display device according to claim 31, wherein the molecular weight of the organic compound in the charge transfer layer is 1,000 or less.
